(19) United States
(12) Patent Application Publication
(10) Pub. No.: US 2025/0293705 A1
(43) Pub. Date: Sep. 18, 2025

(54) DATA COMPRESSION SYSTEM, DATA COMPRESSION METHOD, AND DATA COMPRESSION PROGRAM

(71) Applicant: Hitachi, Ltd., Tokyo (JP)

(72) Inventors: Ko ARAI, Tokyo (JP); Hiroaki AKUTSU, Tokyo (JP); Takahiro NARUKO, Tokyo (JP)

(73) Assignee: Hitachi, Ltd., Tokyo (JP)

(21) Appl. No.: 19/072,872

(22) Filed: Mar. 6, 2025

(30) Foreign Application Priority Data
Mar. 12, 2024 (JP) 2024-038501

(51) Int. Cl. H03M 7/30; G06F 17/16

(52) U.S. Cl. CPC H03M 7/3064; G06F 17/16; H03M 7/6011

(57) ABSTRACT

A computer system for compressing data includes a parallel processing device. The data parallel processing device is configured to divide compression target data into a plurality of pieces of partial data, execute compression processing on the partial data in parallel, calculate an appearance probability for each predetermined data unit of the partial data by using a neural network in the compression processing, and output a coded bit string which is a bit string subjected to entropy coding to the data unit based on the data unit and the appearance probability. Processing of implementing the neural network includes first conversion processing of executing matrix multiplication processing, and second conversion processing of inputting a processing result of the first conversion processing and converting each element of a matrix resulting from the processing result into an integer of 1 bit, subsequent to the first conversion processing.

### BACKGROUND OF THE INVENTION

### 1. Field of the Invention

The present invention relates to a technology for compressing data.

### 2. Description of Related Art

With the advancement of internet of things (IoT), a data generation amount increases significantly, and a data storage amount in hybrid clouds increases. Although storage costs are decreasing, it is not enough to cover growth in a data volume. Therefore, it is important to reduce a data volume stored in a storage. It is also important to reduce a data volume from the viewpoint of reducing a data communication volume.

As a related technique, for example, PTL 1 discloses a technique that can reduce a data volume in a storage by using a neural network. Further, PTL 2 discloses a technique that can reduce a data volume by using an integer neural network.

### CITATION LIST

### Patent Literature

PTL 1: JP2019-95913A
PTL 2: WO2020/068498

### SUMMARY OF THE INVENTION

Although a data volume can be reduced through compression processing, there is a problem that the compression processing takes a long time. When the compression processing takes a long time in such a manner, there is a concern that costs of a calculation resource will increase and other processing will be affected.

The invention was made in view of the above circumstances, and an object thereof is to provide a technique that can improve a processing speed of compression processing.

In order to achieve the above object, a computer system according to one aspect is a data compression system for compressing data. The data compression system includes a parallel processing device. The data parallel processing device is configured to divide compression target data into a plurality of pieces of partial data, execute compression processing on the partial data in parallel, calculate an appearance probability for each predetermined data unit of the partial data by using a neural network in the compression processing, and output a coded bit string which is a bit string subjected to entropy coding to the data unit based on the data unit and the appearance probability. Processing of implementing the neural network includes first conversion processing of executing matrix multiplication processing, and second conversion processing of inputting a processing result of the first conversion processing and converting each element of a matrix resulting from the processing result into an integer of 1 bit, subsequent to the first conversion processing.

According to the invention, a processing speed of compression processing can be improved.

### BRIEF DESCRIPTION OF THE DRAWINGS

FIG. 1 is an overall configuration diagram showing a computer system according to a first embodiment;

FIG. 2 is a configuration diagram showing an address mapping table according to the first embodiment;

FIG. 3 is a configuration diagram showing block data storage information according to the first embodiment;

FIG. 4 is a configuration diagram showing history information according to the first embodiment;

FIG. 5 is a diagram showing an overview of backup processing and restoration processing in the computer system according to the first embodiment;

FIG. 6 is a diagram showing a compressor according to the first embodiment;

FIG. 7 is a diagram showing a decompressor according to the first embodiment;

FIG. 8 is a flowchart showing compression processing executed by the compressor according to the first embodiment;

FIG. 9 is a flowchart showing decompression processing executed by the decompressor according to the first embodiment;

FIG. 10 is a flowchart showing the backup processing according to the first embodiment;

FIG. 11 is a flowchart showing the restoration processing according to the first embodiment;

FIG. 12 is a diagram showing estimation model processing according to the first embodiment;

FIG. 13 is a diagram showing a data flow of the estimation model processing and mixer model processing according to the first embodiment;

FIG. 14 is a diagram showing an algorithm of the estimation model processing according to the first embodiment;

FIG. 15 is a configuration diagram showing a cache information table according to the first embodiment;

FIG. 16 is a configuration diagram showing a parallel processing device according to the first embodiment;

FIG. 17 is a diagram showing matrix multiplication processing and activation function processing according to the first embodiment;

FIG. 18 is a flowchart showing weight matrix quantization processing according to the first embodiment;

FIG. 19 is a flowchart showing the matrix multiplication processing according to the first embodiment;

FIG. 20 is a flowchart showing the activation function processing according to the first embodiment; and

FIG. 21 is a diagram showing a data flow of the matrix multiplication processing and the activation function processing in the parallel processing device according to the first embodiment.

### DESCRIPTION OF EMBODIMENTS

Embodiments will be described with reference to the drawings. The embodiments described below do not limit the invention according to the range of claims, and it is not necessary that all of the elements and combinations described in the embodiments are essential to the solution means of the invention.

In the following description, although information may be described by an expression of “AAA table”, information may be expressed by any data structure. That is, in order to indicate that the information does not depend on the data structure, the “AAA table” can be referred to as “AAA information”.

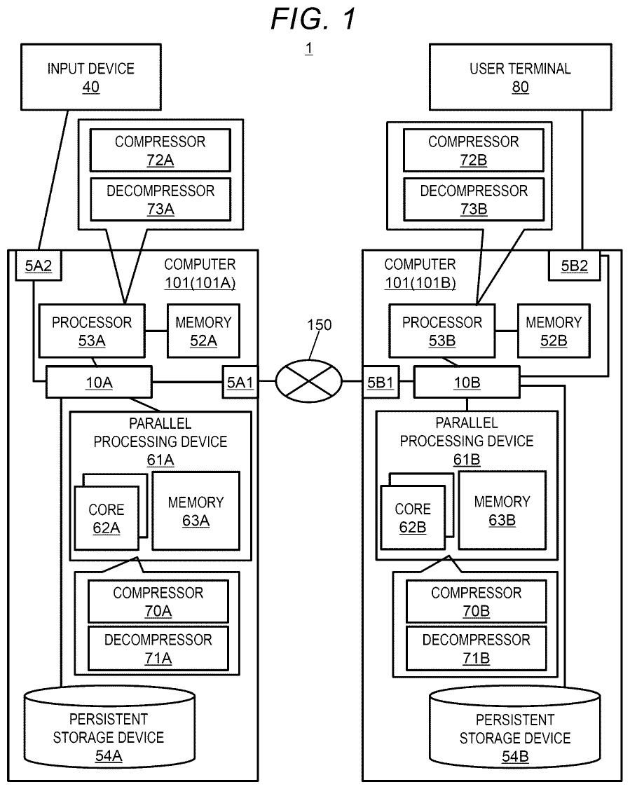

FIG. 1 is an overall configuration diagram showing a computer system according to a first embodiment.

A computer system 1 includes an input device 40, a user terminal 80, a computer 101A, and a computer 101B. The computers 101A and 101B are each an example of a data compression system. Note that the computer system 1 can also be referred to as an example of a data compression system. The computer 101A and the computer 101B are connected to each other via a network 150. The network 150 is, for example, a communication channel such as a wired local area network (LAN), a wireless LAN, a wide area network (WAN), or a dedicated line. The computer 101A is connected to the input device 40. The computer 101B is connected to the user terminal 80. Note that the computer 101A and the computer 101B may be virtual calculation resources (for example, a virtual machine, a container and the like) in a cloud environment.

The input device 40 is implemented by a computer such as a personal computer (PC), and receives input from a user and executes various kinds of processing using data. The input device 40 stores data to be used for processing in the computer 101A, and acquires data from the computer 101A. Note that the input device 40 may be a virtual calculation resource (for example, a virtual machine, a container and the like) in a cloud environment.

The user terminal 80 is implemented by, for example, a computer such as a PC, and receives an instruction from a user to perform setting or the like for the computer 101B. Note that the user terminal 80 may be a virtual calculation resource (for example, a virtual machine, a container and the like) in a cloud environment.

The computer 101A stores and manages data used by the input device 40. The computer 101A executes processing for backing up data to the computer 101B and processing for restoring data from the computer 101B. The computer 101A is implemented by a computer such as a PC or a server device, and includes a processor 53A, a memory 52A, interfaces (IF) 5A1 and 5A2, a parallel processing device 61A, a persistent storage device 54A, and a bus 10A that connects the units to one another.

The IFs 5A1 and 5A2 are interfaces such as wired LAN cards and wireless LAN cards, and communicate with other devices via the network 150 or communication lines.

The processor 53A executes various kinds of processing according to programs stored in the memory 52A. The processor 53A functions as a compressor 72A and a decompressor 73A by executing programs. The processor 53A functions as a first block corresponding guarantee code creation unit and a second block corresponding guarantee code creation unit by executing programs. The compressor 72A executes, for example, compression processing on data. An algorithm for the compressor 72A to execute the compression processing may be gzip, Lempel-Ziv-Markov chain-algorithm (LZMA), or the like. The decompressor 73A decompresses compressed data. An algorithm for the decompressor 73A to execute decompression processing may be an algorithm corresponding to the compression processing executed by the compressor 72A.

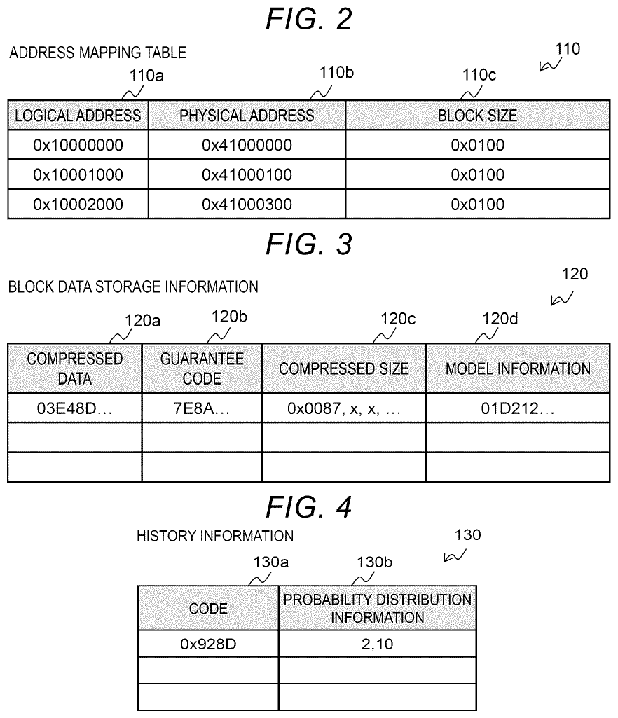

The memory 52A is, for example, a random access memory (RAM), and stores programs to be executed by the processor 53A and necessary information. In the present embodiment, the memory 52A stores, for example, an address mapping table 110 (refer to FIG. 2).

The persistent storage device 54A is, for example, a hard disk or a flash memory, and stores programs read to the memory 52A for the processor 53A to execute the programs and various kinds of data used by the processor 53A. In the present embodiment, the persistent storage device 54A stores a data compression program as a program, and stores block data storage information 120 (refer to FIG. 3) and the address mapping table 110 (refer to FIG. 2) as data. Note that, instead of or in addition to the persistent storage device 54A, a storage on a cloud connected via a network may be used. Note that the persistent storage device 54A and the storage on the cloud may be implemented by a block storage, a file storage, an object storage, a database, and the like.

The parallel processing device 61A is, for example, a device that can execute processing in parallel, such as a graphics processing unit (GPU), an application specific integrated circuit (ASIC), a field programmable gate array (FPGA), or a multi-core central processing unit (CPU), and includes a plurality of cores 62A and a memory 63A. The core 62A executes processing according to a program stored in the memory 63A. The memory 63A is an example of a storage unit, and stores a program to be executed by the core 62A and data used by the core 62A. The memory 63A stores, for example, history information 130 (refer to FIG. 4). The plurality of cores 62A can execute various kinds of processing in parallel using the memory 63A. In the present embodiment, the parallel processing device 61A functions as a compressor 70A and a decompressor 71A by executing programs. In the present embodiment, compression by the compressor 70A can compress data higher than compression by the compressor 72A.

The computer 101B stores and manages data managed by the computer 101A. The computer 101B is implemented by a computer such as a PC or a server device, and includes a processor 53B, a memory 52B, IFs 5B1 and 5B2, a parallel processing device 61B, a persistent storage device 54B, and a bus 10B that connects the units to one another. The processor 53B functions as a compressor 72B and a decompressor 73B which is an example of a decompression unit. The parallel processing device 61B includes a plurality of cores 62B and a memory 63B, and functions as a compressor 70B and a decompressor 71B. Each configuration of the computer 101B is similar to each configuration of the computer 101A, which has the same number in the first half of the reference numeral. Note that the configurations of the computer 101A and the computer 101B are not limited to those described above, and some of the configurations may not be provided depending on processing to be executed.

Next, the address mapping table 110 will be described.

FIG. 2 is a configuration diagram showing the address mapping table according to the first embodiment.

The address mapping table 110 is a table that manages a physical address corresponding to a logical address which is a storage destination of data, and stores an entry for each area (for example, block) of a predetermined size. An entry in the address mapping table 110 includes fields of a logical address 110a, a physical address 110b, and a block size 110c. The logical address 110a stores a logical address indicating an area corresponding to an entry. The physical address 110b stores a physical address corresponding to the area corresponding to the entry. The block size 110c stores a block size of the area corresponding to the entry.

Next, the block data storage information 120 will be described.

FIG. 3 is a configuration diagram showing the block data storage information according to the first embodiment.

The block data storage information 120 is information for managing block data, and includes an entry for each piece of block data. An entry of the block data storage information 120 includes fields of compressed data 120a, a guarantee code 120b, and a compressed size 120c. The compressed data 120a stores compressed data obtained by compressing the block data. The guarantee code 120b stores a guarantee code for the block data. The compressed size 120c stores a data size of the compressed data. Compression target data is compressed by dividing the compression target data into a plurality of pieces of partial data. Thus, each piece of partial data has a compressed size, and partial recompression and decompression can be performed without decoding the partial data that is not included in a data location to be partially recompressed or decompressed. Model information 120d stores an overall learned model (model in an initial state of an estimation model or a mixer model). Alternatively, by storing reference information of other corresponding models (models corresponding to other block data that was already learned), a data volume of block data storage information may be reduced. The model information 120d may store integer accuracy of a layer of a model.

Next, the history information 130 will be described.

FIG. 4 is a configuration diagram showing the history information according to the first embodiment.

The history information 130 is information for managing a probability distribution corresponding to data used when calculating an appearance probability for a data unit (data used during calculation), and includes an entry for each piece of data used during calculation. An entry of the history information 130 includes fields of a code 130a and probability distribution information 130b. The code 130a stores a predetermined code (identification information) for the data used during calculation, which corresponds to an entry. The code may be a hash value or locality sensitive hashing (LSH) for the data used during calculation. The probability distribution information 130b stores information on a probability distribution calculated using the data used during calculation, which corresponds to the entry. The information on the probability distribution may be an appearance frequency of a target data unit or a learning code based on deep neural network (DNN). The history information 130 is stored, for example, when the core 62B executes a program. A function of the core 62B corresponds to a history management unit.

Next, an overview of backup processing and restoration processing in the computer system 1 will be described.

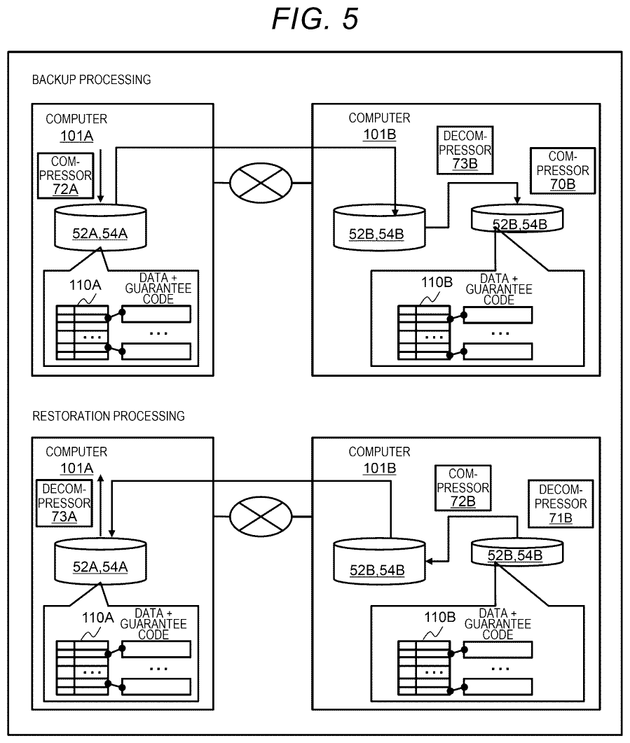

FIG. 5 is a diagram showing an overview of the backup processing and the restoration processing in the computer system according to the first embodiment.

First, the backup processing will be described. In the backup processing, the compressor 72A of the computer 101A compresses backup target data, creates a guarantee code and associates the guarantee code with the backup target data using a predetermined block size (first size) as a unit, and stores the backup target data and the guarantee code in the memory 52A or the persistent storage device 54A.

The computer 101A refers to an address mapping table 110A, specifies a storage location of the backup target data in the memory 52A or the persistent storage device 54A, acquires the backup target data and the guarantee code, and transmits the backup target data and the guarantee code to the computer 101B which is a backup destination.

The computer 101B stores the received backup target data and guarantee code in the memory 52B or the persistent storage device 54B, and executes decompression processing on the backup target data using the decompressor 73B. In the decompression processing, the guarantee code is used to detect and correct an error in the backup target data. Next, the compressor 70B compresses the decompressed backup target data, creates a guarantee code using a block of a predetermined block size (second size) as a unit, stores the created guarantee code in the memory 52B or the persistent storage device 54B, and registers a storage destination in an address mapping table 110B. However, for partial updating (compressing only a part to be updated without decompressing an entire block), for example, a method may be adopted in which a guarantee code that can be partially updated, such as an XOR parity, is used in units of blocks. Alternatively, a guarantee code may be created for each piece of partial data to support partial updating.

According to the backup processing, the backup target data can be saved in a highly compressed state by the compressor 70B. When the second size is set to be larger than the first size and a guarantee code is created using the second size as a data unit, an overall data volume can be reduced. Note that the decompression processing executed by the decompressor 73B of the computer 101B may be executed by the decompressor 73A of the computer 101A, and the decompressed data may be transmitted to the computer 101B.

Next, the restoration processing will be described. In the restoration processing, a case will be described in which the computer 101B is instructed to use data that was backed up in the backup processing and is transmitted from the computer 101A as restoration target data. First, the decompressor 71B of the computer 101B refers to the address mapping table 110B, specifies a storage location of the backup target data in the memory 52B or the persistent storage device 54B, acquires restoration target data and a guarantee code, and executes decompression processing. In the decompression processing, the guarantee code is used to detect and correct an error in the restoration target data.

Next, the compressor 72B compresses the decompressed restoration target data using an algorithm according to which decompression by the decompressor 73A of the computer 101A is possible, creates a guarantee code using the first size as a unit, stores the created guarantee code in the memory 52B or the persistent storage device 54B, and transmits the compressed restoration target data and the guarantee code to the computer 101A which is a restoration destination.

The computer 101A stores the received restoration target data and guarantee code in the memory 52A or the persistent storage device 54A, and registers a storage destination in the address mapping table 110A. Next, the decompressor 73A executes decompression processing on the restoration target data. In the decompression processing, the guarantee code is used to detect and correct an error in the restoration target data. Accordingly, the computer 101A can use the restoration target data.

Next, configurations and processing of a compressor 70 (70A, 70B) will be described.

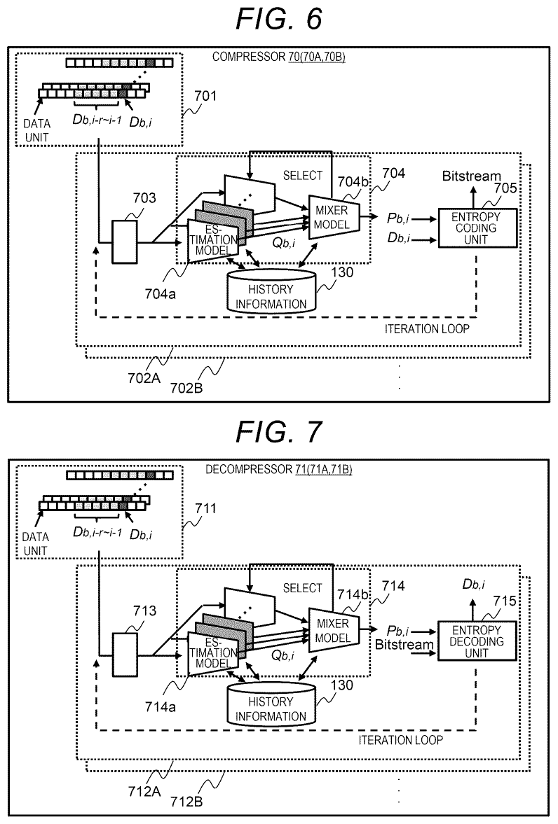

FIG. 6 is a diagram showing the compressor according to the first embodiment.

The compressor 70 includes a data division unit 701 and a plurality of compression processing units 702 (702A, 702B, and the like). Each of the compression processing units 702 is implemented by a core 62 (62A, 62B) of a parallel processing device 61 (61A, 61B) executing a program in a memory 63 (63A, 63B), wherein, a learning unit and a model selection unit are implemented by the compression processing units 702 executing programs.

The data division unit 701 divides the compression target data into a plurality of pieces of partial data (for example, 1 KB). In the present embodiment, the data division unit 701 divides data into partial data by the number of batches B to be executed in parallel. In the compressor 70, the compression processing units 702 with the same number as the number of batches B are used for processing, and the compression processing units 702 execute the compression processing on respective pieces of partial data. The compression target data can be divided into a larger number of pieces of partial data by simultaneously processing a plurality of pieces of block data together, thereby increasing, for example, parallelism of processing in the parallel processing device 61B and speeding up the processing.

The compression processing unit 702 includes a pre-coding unit 703 which is an example of a conversion unit, a probability calculation unit 704, and an entropy coding unit 705.

When partial data to be compressed is binary data, the pre-coding unit 703 executes one-hot encoding for each data unit of a predetermined size (u bits) included in the partial data. One data unit is converted into 2u bits by the pre-coding unit 703. Data coded by the pre-coding unit 703 becomes the number of channels (C) to be input to the probability calculation unit 704. Note that, when one-hot encoding is executed, for a value of one predetermined bit of coded data for one data unit, the value can be specified according to values of remaining bits, and thus the predetermined one bit of the coded data may be deleted to make the number of channels C=2u−1. By reducing the number of channels in such a manner, a data volume input to the probability calculation unit 704 can be reduced. Note that data used as inputs to a plurality of probability calculation units 704 is an array of the number of batches of partial data (B)×the number of channels (C)×length (N). Note that auxiliary information may be further added to a channel dimension of the data used as inputs. For example, by bit-encoding and adding the logical address 110a in units of bits corresponding to the partial data (adding the number of bits corresponding to a maximum value of a logical address in addition to the 2u bits), accuracy of an estimation model for target data can be improved, and a compression rate can be improved. When the partial data to be compressed is numerical data or when the partial data to be compressed is binary data and can be expressed as a numerical value (such as sensor data or image data), the pre-coding unit 703 may input the partial data to be compressed to the probability calculation unit 704 as numerical data. Generally, it is assumed that a numerical data file and texts or a binary data file coexist in data on a storage, and thus, for more efficient compression, a plurality of models such as an estimation model 704a for numerical data and an estimation model 704a for texts or a binary data file may be prepared.

Further, the pre-coding unit 703 calculates a hash value for the partial data to be compressed, and compares data with the hash value to detect overlapping with previously processed partial data. For overlapping data, the pre-coding unit 703 saves only reference information to the previously processed partial data in the address mapping table 110 or the block data storage information 120, and accordingly, it is not necessary to recompress and save the same data, and a compression rate can be increased. Here, subsequent compression processing may be omitted to speed up the processing.

The probability calculation unit 704 includes a plurality of types of the estimation models 704a and mixer models 704b.

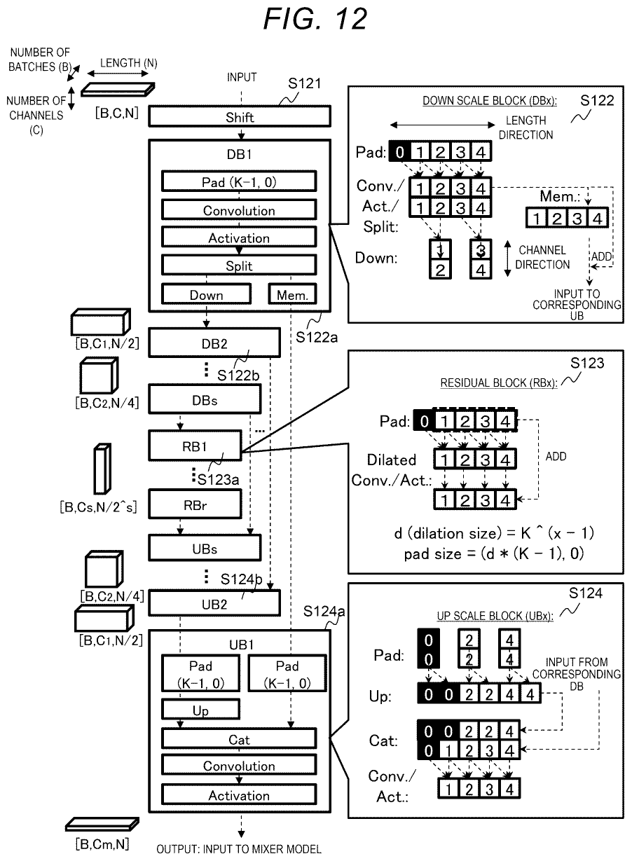

The estimation model 704a outputs estimation information Qb,i in an estimation target data unit by inputting data (estimation data) used to estimate a data unit of which an appearance probability is to be estimated (estimation target data unit) and probability distribution information of the history information 130, wherein, the estimation data may use, for example, a data unit of data units Db,i−r to Db,i−1, where the estimation target data unit is Db,i (i is a location of the estimation data unit in the partial data), that is, may use r data units immediately before the estimation target data unit. Note that, when r data units do not exist immediately before Db,i, processing is executed on an assumption that missing data units have a predetermined value. The estimation model 704a may be a model implemented by a plurality of learnable weights such as a neural network, or may be a model configured to execute specific predefined processing. The estimation model 704a may output the appearance probability as the estimation information Qb,i, or may output a feature map of a location corresponding to the estimation target data unit. When the appearance probability is output as the estimation information Qb,i, a discrete probability (such as a categorical distribution) may be output as the appearance probability for each symbol, parameters (average, variance, and the like) of a continuous probability density function such as a Gaussian distribution may be output, or a result of calculating a discrete probability corresponding to the appearance probability of each symbol from a cumulative distribution function of a continuous probability density function may be output. An example of a configuration of the estimation model 704a will be described later with reference to FIGS. 12 to 14.

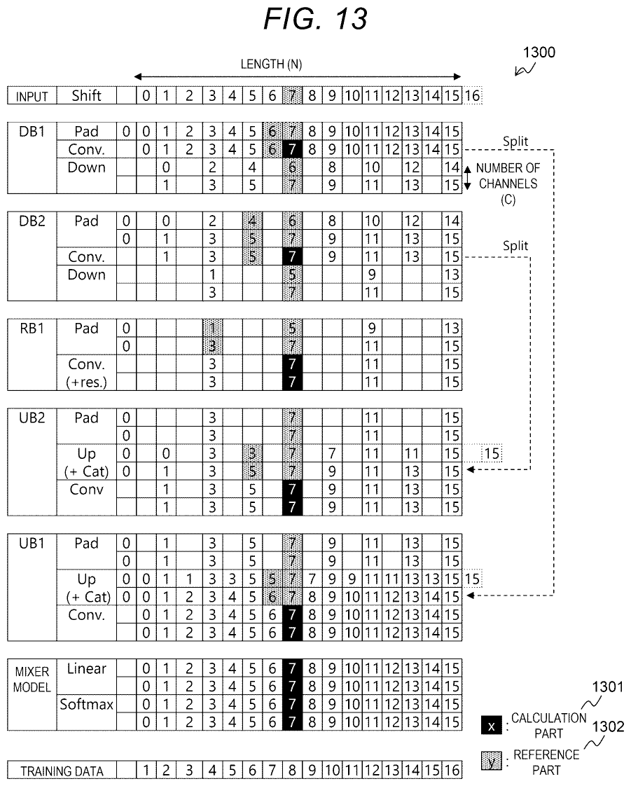

The mixer model 704b outputs (calculates) an appearance probability Pb,i of an estimation target data unit by inputting estimation information output from a plurality of types of the estimation models 704a and probability distribution information of the history information 130. The appearance probability Pb,i is a distribution of an appearance probability for each symbol in a data unit, the mixer model 704b may output a discrete probability (such as a categorical distribution), and may output parameters (average, variance, and the like) of a continuous probability density function such as a Gaussian distribution as the appearance probability, and may use a result obtained by calculating a discrete probability corresponding to the appearance probability for each symbol from a cumulative distribution function during entropy coding. That is, when one-hot encoding is performed, the number of elements is the same as the number of channels input to probability calculation unit 704 (C=2u or 2u−1). The mixer model 704b is a model such as a neural network, and may be, for example, a gated linear network that integrates values input from the estimation model 704a using learned weights, or may be implemented by a perceptron. Attention processing based on an output result of the estimation model (multiplying data processed in the mixer model 704b by a value corresponding to a degree of importance calculated from the output result of the estimation model) may be included. In the present embodiment, the probability calculation unit 704 selects an estimation model to be used for processing from a plurality of types of the estimation models 704a, based on a weight for each estimation model 704a in the mixer model 704b. Note that the history information 130 may be provided for each compression processing unit 702 or may be shared by a plurality of the compression processing units 702. In particular, when each data unit has locality, by sharing the history information 130, it is possible to increase the number of statistical samples of the probability distribution, and thus estimation accuracy can be improved, a compression rate can be increased, and usage of the memory 63B or the like can be saved. An example of the configuration of the mixer model 704b will be described later with reference to FIG. 13.

The entropy coding unit 705 takes the appearance probability Pb,i output from the probability calculation unit 704 and a data unit Db,i as inputs, and outputs a bit string (coded bit string) obtained by entropy-coding the data unit Db,i.

Each of the compression processing units 702 entropy-codes the entire partial data by sequentially changing compression targets and repeating the processing, for example, from a data unit at the head, by using a data unit in the partial data as a unit. Processing executed by the compression processing units 702 is executed in parallel, for example, in a dimension of the number of batches (B), and thus efficiency of the compression processing can be improved. Since results of a plurality of estimation models are integrated to calculate the appearance probability, a highly accurate appearance probability can be calculated and compression efficiency can be improved.

The compressor 70 collects bit streams (second block corresponding bit string group) for each piece of the partial data obtained by the plurality of compression processing units 702 in a state where a data range corresponding to each piece of the partial data is identifiable, and uses the collected bit streams as compressed data of the compression target data, wherein, a storage processing unit is implemented by the compressor 70.

Next, a configuration and processing of a decompressor 71 (71A, 71B) will be described.

FIG. 7 is a diagram showing the decompressor according to the first embodiment.

The decompressor 71 decompresses the compressed data compressed by the compressor 70. The decompressor 71 includes a data synthesis unit 711 and a plurality of decompression processing units 712 (712A, 712B, and the like).

Each of the decompression processing units 712 is implemented by the core 62 (62A, 62B) of the parallel processing device 61 (61A, 61B) executing a program in the memory 63 (63A, 63B), wherein, the first block corresponding guarantee code creation unit is implemented by the decompressor 71 executing a program.

The data synthesis unit 711 synthesizes partial data implemented by a data unit decompressed by each decompression processing unit 712 to generate data before compression. In the present embodiment, the data synthesis unit 711 synthesizes partial data of the number of batches B during compression of the compressed data. In the decompressor 71, the decompression processing units 712 with the same number as the number of batches B are used for processing, and each decompression processing unit 712 executes decompression processing on each piece of partial data.

The decompression processing unit 712 includes a pre-coding unit 713, a probability calculation unit 714 which is an example of a second probability calculation unit, and an entropy decoding unit 715.

The pre-coding unit 713 executes the same processing as the pre-coding unit 703. The probability calculation unit 714 executes the same processing as the probability calculation unit 704.

When the appearance probability Pb, i output from the probability calculation unit 714 and a bit string corresponding to the data unit Db, i to be decoded in the compressed data are input, the entropy decoding unit 715 decodes the bit string and outputs the data unit Db,i.

Each decompression processing unit 712 entropy-decodes the entire bit string of the entropy-coded partial data by sequentially changing decompression targets and repeating the processing, for example, from a data unit at the head, for each data unit in the partial data. Processing executed by the decompression processing units 712 is executed in parallel, for example, in a dimension of the number of batches (B), and thus efficiency of the decompression processing can be improved.

Next, a processing operation of the compression processing executed by the compressor 70 will be described.

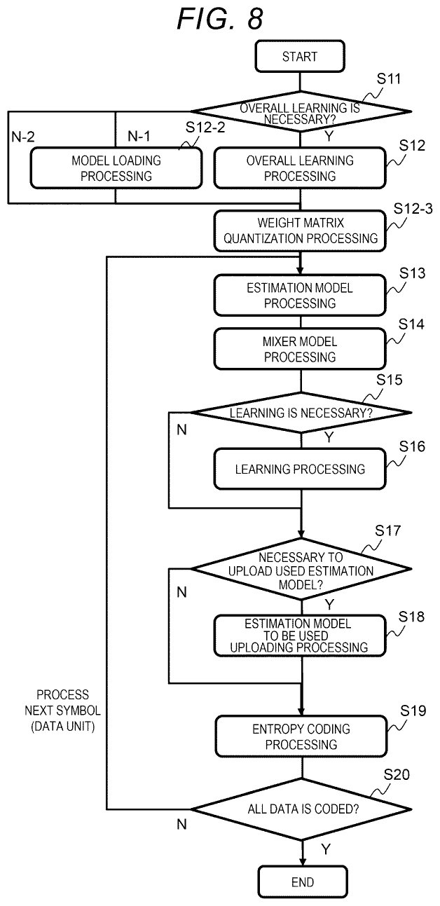

FIG. 8 is a flowchart showing the compression processing executed by the compressor according to the first embodiment. Note that the compression processing shown in FIG. 8 is processing executed by each compression processing unit 702 of the compressor 70, and can be implemented by, for example, a thread operating in the core 62B of the parallel processing device 61B.

The compression processing unit 702 of the compressor 70 determines whether overall learning is necessary (S11). For example, whether overall learning is necessary is determined based on a total compression effect of combining an effect that compression target data can be highly compressed by overall learning a new model and an overhead of a storage capacity for saving the newly learned model.

As a result, when it is determined that the overall learning of the estimation model 704a or the mixer model 704b is necessary (S11: Y), the compression processing unit 702 executes overall learning processing (S12), and a corresponding model is used in estimation model processing and mixer model processing in subsequent processing. The overall learning processing is processing of using data that are close to each other in a logical address space for learning and saving the learned model, based on a hypothesis that the data that are close to each other in the logical address space has similar characteristics of appearance probabilities of data symbols. Learning data may be partial data of compression target data designated at the time of activating the processing flow, or may be other kinds of data. For example, the learning data may be randomly sampled from data stored in a storage based on a predetermined rule. The learned model is saved as the model information 120d in the block data storage information 120 in association with the compressed data. Alternatively, by storing reference information of other corresponding models (models corresponding to other kinds of block data that was already learned) (that is, reusing a model that was already learned), a processing time of overall learning and a data volume in the block data storage information may be reduced. In the learning, a technique such as transfer learning and meta-learning may be used to speed up the learning.

On the other hand, when it is determined that overall learning is not necessary, if a model is not stored in the memory 63B (S11: N−1), the compression processing unit 702 executes model loading processing of loading a model to the memory 63B (S12-2), and if a model is stored in the memory 63B (S11: N−2), the compression processing unit 702 proceeds the processing to step S12-3.

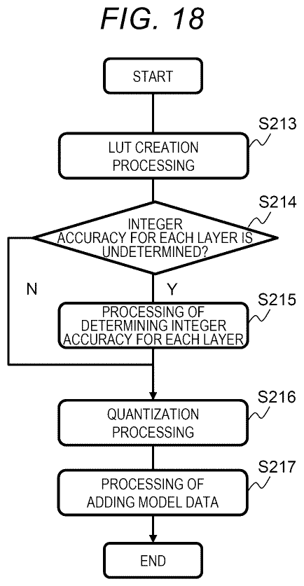

Next, the compression processing unit 702 causes the processor 53B to execute weight matrix quantization processing (refer to FIG. 18) of quantizing a weight matrix used in the model (S12-3).

Next, the compression processing unit 702 executes one-hot encoding as necessary on data used for calculating the appearance probability of a compression target data unit (compression target data unit: at first, a data unit at the head, and thereafter, a next data unit) of partial data that the compression processing unit 702 is in charge of, and executes the estimation model processing of inputting the data into the plurality of estimation models 704a and calculating a plurality of appearance probabilities using the plurality of estimation models (S13).

Next, the compression processing unit 702 executes the mixer model processing of inputting a plurality of pieces of estimation information calculated in the estimation model processing into the mixer models 704b, and calculating an appearance probability of the compression target data unit (S14).

Next, the compression processing unit 702 determines whether learning of the estimation model 704a and the mixer model 704b is necessary (S15). For example, it may be determined that learning is necessary when the determination in step S15 is executed a predetermined number of times.

As a result, when it is determined that learning of the mixer model 704b is necessary (S15: Y), the compression processing unit 702 executes processing of learning the estimation model 704a and the mixer model 704b (S16), and then proceeds the processing to step S15. Data used in the learning is data that was already decoded at this point when decompression is assumed, and may be data prepared in advance and/or history data. According to the learning processing, weights stored by the plurality of estimation models 704a and the mixer models 704b are corrected.

On the other hand, when it is determined that learning of the mixer model 704b is not necessary as a result (S15: N), the compression processing unit 702 proceeds the processing to step S17.

In step S17, the compression processing unit 702 determines whether it is necessary to update an estimation model actually to be used among the plurality of estimation models. For example, as a weight for each estimation model is changed by learning of the mixer model 704b, when the weight for the estimation model is equal to or less than a predetermined threshold, it may be determined that the estimation model to be used needs to be updated.

As a result, when it is determined that the estimation model to be used needs to be updated (S17: Y), the compression processing unit 702 executes the estimation model to be used updating processing (S18), in which an estimation model of which a corresponding weight is equal to or less than a predetermined value among the estimation models is set to be not used, and proceeds the processing to step S19.

On the other hand, when it is determined that it is not necessary to update the estimation model to be used (S17: N), the compression processing unit 702 proceeds the processing to step S19.

In step S19, the compression processing unit 702 converts the compression target data unit into an entropy-coded bit string by executing entropy coding processing using the appearance probability output in step S14 and the compression target data unit.

Next, the compression processing unit 702 determines whether all data units of the partial data are coded (S20), and when not all data units are coded (S20: N), the compression processing unit 702 proceeds the processing to step S13 to process a next data unit.

On the other hand, when all data units are coded (S20: Y), the processing ends. Thereafter, the compressor 70 collects coded bit strings of the partial data converted by each compression processing unit 702 and stores the bit strings as compressed data in a predetermined storage location.

Although an example is described in the above description in which the estimation model processing, the mixer model processing, the learning processing, and the entropy coding processing are iterated in order for each data unit, an execution unit and a timing of the processing can be changed. For example, in the estimation model processing and the mixer model processing, since all original data is present during compression, for example, the processing can be executed collectively in parallel in a length (N) direction as shown in FIG. 12. When a method such as asymmetric numeral systems (ANS) is used in the entropy coding processing (S19), since the decoding processing needs to be executed in a reversed order of the coding processing, during compression, the appearance probability as a result estimated in the estimation model processing and the mixer model processing is saved in the length (N) direction, and when a series of calculations in the length (N) direction is completed, the entropy coding processing is executed collectively in a reversed order for the saved appearance probability. In the learning processing, in addition to a method of executing processing in the length (N) direction (learning using data before a current time point of iteration in the length (N) direction), for example, a plurality of data blocks to be compressed may be sampled and used as learning target data. Here, to ensure that the learning target data can be uniquely specified and are not included in data before decompression, sampling may be executed using deterministic pseudorandom numbers and the like to determine learning data and a schedule during compression. A processing order of data units in the length (N) direction does not have to be an original order, and processing may be executed by changing the processing order using a reversible algorithm. A method such as a diffusion model that restores original data from a noise state may be used, and an iteration unit may correspond to one step of the diffusion model. When changing an execution unit and timing as described above, in any case, by executing decompression using the same execution unit and timing, and by setting appearance probabilities which are estimated results to be the same, decoding is possible.

Next, a processing operation of the decompression processing executed by the decompressor 71 will be described.

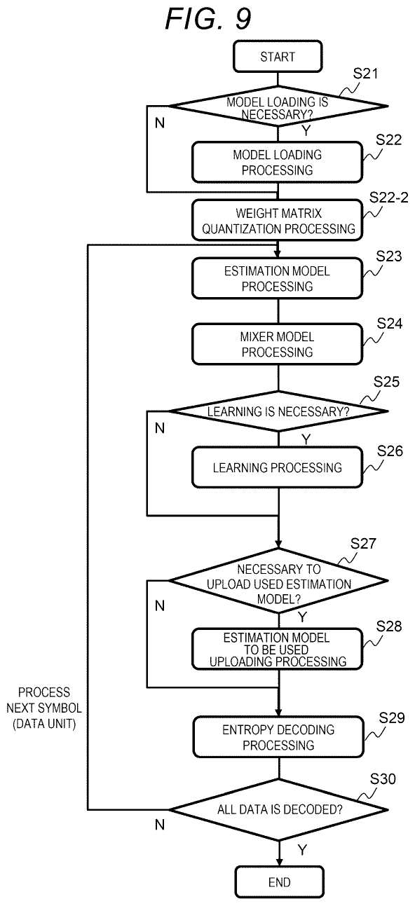

FIG. 9 is a flowchart showing the decompression processing executed by the decompressor according to the first embodiment. Note that the decompression processing shown in FIG. 9 is processing executed by each decompression processing unit 712 of the decompressor 71, and can be implemented by, for example, a thread operating in the core 62B of the parallel processing device 61B.

The decompression processing unit 712 of the decompressor 71 determines whether model loading is necessary (S21). For example, regarding whether model loading is necessary, when a parameter and a reference of a model are saved in association with compressed data as the model information 120d in the block data storage information 120, it is determined that model loading is necessary, and when the parameter and the reference are not saved, it is determined that model loading is not necessary.

As a result, when it is determined that model loading of the estimation model 704a or the mixer model 704b is necessary (S21: Y), a model is arranged in the memory 63B of the parallel processing device 61B as the model information 120d based on the parameter and the reference of the model corresponding to the compressed data (S22). The memory 63B of the parallel processing device 61B may be used like a cache. In this case, when it is determined in S21 that a model is already loaded into the memory 63B used as a cache (model that is used frequently may be arranged in the memory 63B as a cache), model loading can be omitted, and thus it can be determined that model loading is not necessary, and a time required for model loading can be efficiently reduced.

On the other hand, when it is determined that model loading is not necessary (S21: N), the decompression processing unit 712 proceeds the processing to step S22-2.

Next, the decompression processing unit 712 causes the processor 53B to execute the weight matrix quantization processing (refer to FIG. 18) of quantizing a weight matrix used in the model (S22-2).

Next, the decompression processing unit 712 executes one-hot encoding on data used for calculating an appearance probability of a decompression target data unit (decompression target data unit: at first, a data unit at the head, and thereafter, a next data unit) of partial data that the decompression processing unit 712 is in charge of, and executes estimation model processing of inputting data into the plurality of estimation models 714a and calculating a plurality of pieces of estimation information using the plurality of estimation models (S23).

Next, the decompression processing unit 712 executes mixer model processing of inputting the plurality of pieces of estimation information calculated by the estimation model processing into the mixer model 714b, and calculating the appearance probability of the decompression target data unit (S24).

Next, the decompression processing unit 712 determines whether learning of the estimation model 714a and the mixer model 714b is necessary (S25). For example, it may be determined that learning is necessary when the determination in step S25 is executed a predetermined number of times.

As a result, when it is determined that learning of the estimation model 714a and the mixer model 714b is necessary (S25: Y), the decompression processing unit 712 executes processing of learning the estimation model 714a and the mixer model 714b (S26), and then proceeds the processing to step S27. Data used for the learning processing is data that is already decoded at this time point, and may be data prepared in advance and/or history data. According to the learning processing, weights stored by the estimation model 714a and the mixer model 714b are corrected.

On the other hand, when it is determined that learning of the estimation model 714a and the mixer model 714b is not necessary as a result (S25: N), the decompression processing unit 712 proceeds the processing to step S27.

In step S27, the decompression processing unit 712 determines whether it is necessary to update an estimation model actually to be used among the plurality of estimation models. For example, as a weight for each estimation model is changed by learning the mixer model 714b, when the weight for the estimation model is equal to or less than a predetermined threshold, it may be determined that the estimation model to be used needs to be updated.

As a result, when it is determined that it is necessary to update the estimation model to be used (S27: Y), the decompression processing unit 712 executes the estimation model to be used updating processing (S28), in which an estimation model of which a corresponding weight is equal to or less than a predetermined value among the estimation models is set to be not used, and proceeds the processing to step S29.

On the other hand, when it is determined that it is not necessary to update the estimation model to be used (S27: N), the decompression processing unit 712 proceeds the processing to step S29.

In step S29, the decompression processing unit 712 executes entropy decoding processing using the appearance probability output in step S24 and an entropy-coded bit string corresponding to the decompression target data unit to decode the entropy-coded bit string into a data unit before coding.

Next, the decompression processing unit 712 determines whether all data units of the partial data are decoded (S30), and when not all data units are decoded (S30: N), the decompression processing unit 712 proceeds the processing to step S23 to process a next data unit.

On the other hand, when all data units are decoded (S30: Y), the decompression processing unit 712 ends the processing. Thereafter, the decompressor 71 collects the partial data converted by each decompression processing unit 712 and stores the collected partial data as decompressed data in a predetermined storage location.

As described above, each processing necessary for decompressing a plurality of data units by the decompression processing unit 712 is consistently executed in a loop on a thread operating in the core 62B of the parallel processing device 61B, and accordingly, it is possible to reduce a processing time required for activating communication or thread necessary for command transmission or the like between the processor 53B and the core 62B of the parallel processing device 61B, and the processing can be speed up. Note that the calculation of the appearance probability of the data unit, the learning processing, the used model updating processing, and other determination processing in steps S23 to S30 are the same as the calculation of the appearance probability of the data unit in the compression processing, and thus for the same data unit, the same appearance probability can be calculated, and the same data unit can be appropriately decoded.

For the compression processing and the decompression processing described in FIGS. 8 and 9, when the learning processing and the estimation model to be used updating processing in S16, S18, S24, and S26 are not operated, or when a state of each piece of partial data is managed and operated independently, it is possible to execute recompression processing or decompression processing for new data updating for each piece of partial data of data to be compressed and decompressed, based on the compressed size 120c in the block data storage information 120. As a result, even when a large block (for example, several MB to several GB) was already highly compressed, it is possible to partially update and decompress data in units of partial data without decompressing all pieces of data in the block, and thus an amount of required calculation resources can be reduced.

Next, a processing operation of backup processing in the computer 101B will be described.

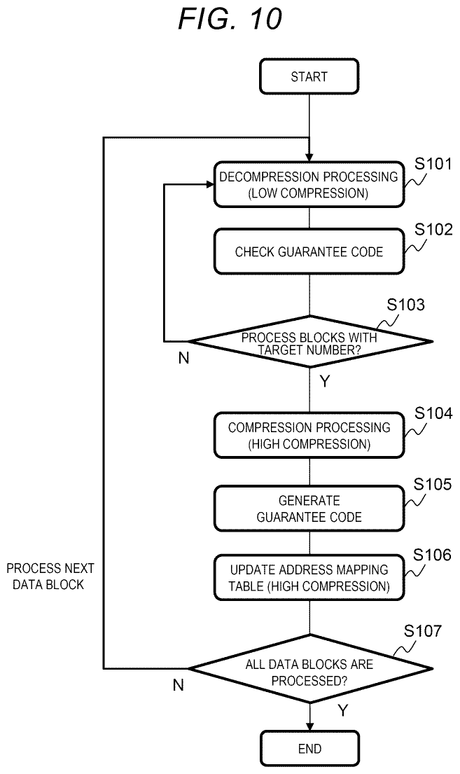

FIG. 10 is a flowchart showing the backup processing according to the first embodiment.

The backup processing is executed when the processor 53B of the computer 101B receives, from the computer 101A, a compression command to which a backup target data block group (first compressed data) compressed by the compressor 72A and a guarantee code group are added. The processor 53B causes the decompressor 73B to execute decompression processing on one backup target data block (first block unit) (S101). Note that the compression executed by the compressor 72A is compression lower than the compression executed by the compressor 70B.

Next, the processor 53B checks data that is decompressed (decompressed data) by using the added guarantee code, and executes processing such as error detection or correction (S102).

Next, the processor 53B determines whether the decompression processing is executed on blocks with the number (number of target blocks) corresponding to a predetermined size (second size) to be compressed in next compression processing (S103).

As a result, when the decompression processing is not executed on blocks with a target number (S103: N), the processor 53B proceeds the processing to step S101 and executes the processing on a next data block.

On the other hand, when the decompression processing is executed on blocks with the target number (S103: Y), the processor 53B causes the compressor 70B to execute the compression processing on data of the blocks (second block unit) with the target number (S104). The compression processing executed by the compressor 70B is the compression processing shown in FIG. 8, and the compression executed by the compressor 70B is higher than the compression executed by the compressor 72. Note that the throughput of the compression processing can be improved by dividing the data of blocks with the target number into a plurality of data units, and for example, by collectively compressing the data in parallel by the cores 62B of the parallel processing device 61B. Since a size of data to be compressed (second size) is larger than a size of data compressed by the compressor 72 (first size), compression efficiency is good.

Next, the processor 53B generates a guarantee code for the data of blocks (second block unit) with the target number (S105), stores the compressed data 120a, the guarantee code 120b, the compressed size 120c, and the model information 120d as the block data storage information 120 in the persistent storage device 54B, and updates the address mapping table 110 according to the stored content (S106), wherein, since the guarantee code is generated for the data of the second size, a storage area required to store the guarantee code can be reduced. When collecting a plurality of data blocks in the first block unit to form a second block unit, zero-filled data may be prepared for an area to which no physical address was originally assigned in the first block unit, and data necessary for restoration equivalent to the address mapping table 110 in the first block unit may be saved together with the block data storage information. When it is necessary to save the address mapping table 110 in the persistent storage device 54, by compressing the address mapping table 110 in a similar manner as a target of the compression processing (S104), a capacity used in the persistent storage device 54 may be saved, and efficiency may be improved. Further, the guarantee code 120b and the model information 120d may also be compressed in a similar manner as a target of compression processing (S104). The compressed size 120c is obtained as a result of the compression processing (S104), and thus compression efficiency may be improved by performing the same processing as the compression processing (S104) again or by using another general compression method.

Next, the processor 53B determines whether all compression target data blocks are processed (S107). As a result, when not all compression target data blocks are processed (S107: N), the processor 53B proceeds the processing to step S101 and executes the processing on a remaining data block.

On the other hand, when all compression target data blocks are processed (S107: Y), the processor 53B notifies the computer 101A, which is a request source, that the backup is completed, and ends the processing.

Next, a processing operation of restoration processing in the computer 101B will be described.

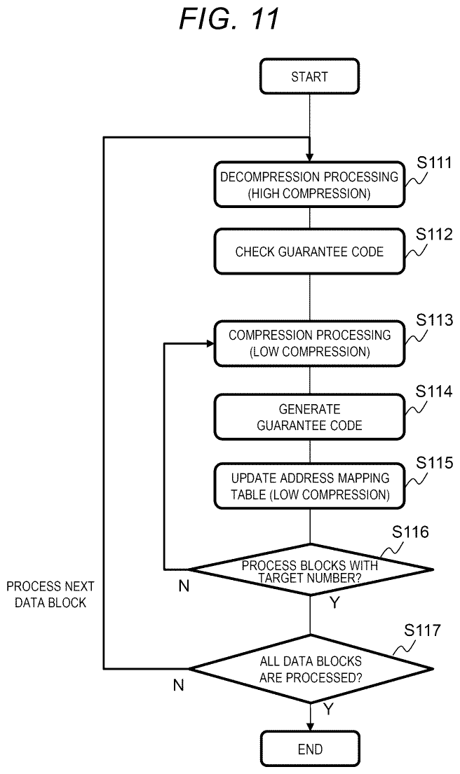

FIG. 11 is a flowchart showing the restoration processing according to the first embodiment.

The restoration processing is executed when the processor 53B of the computer 101B receives, from the computer 101A, a restoration command to which information indicating a restoration target data block group is added. Note that data blocks of the data block group are blocks obtained by compressing data of the first size.

First, the processor 53B causes the decompressor 71B to execute decompression processing on one data block of the second size included in the restoration target data block group corresponding to the restoration command (S111). Note that, similar to the compression, the throughput of the decompression processing can be improved by dividing data with the number of target blocks into a plurality of data units, and for example, by collectively decompressing the data in parallel by the cores 62B of the parallel processing device 61B.

Next, the processor 53B checks the decompressed data using an added guarantee code, and executes processing such as error detection or correction (S112).

Next, the processor 53B causes the compressor 72B to execute compression processing on block data of the first size in the decompressed data (S113).

Next, the processor 53B generates a guarantee code for the block data of the first size (S114), stores the block data and the guarantee code in the persistent storage device 54B, and updates the address mapping table 110 for the block of the first size according to the stored contents (S115).

Next, the processor 53B determines whether the compression processing is executed on blocks with the number of blocks of the first size (the number of target blocks) included in the block data of the second size (S116).

As a result, when the compression processing is not executed on blocks with the number of target blocks (S116: N), the processor 53B proceeds the processing to step S113, and executes the processing for remaining block data of the first size.

On the other hand, when the compression processing is executed on blocks with the number of target blocks (S116: Y), the processor 53B determines whether the processing is executed on all data blocks included in the restoration target data block group (S117).

As a result, when not all data blocks included in the restoration target data block group are processed (S117: N), the processor 53B proceeds the processing to step S111 and executes the processing for a remaining data block.

On the other hand, when all data blocks included in the restoration target data block group are processed (S117: Y), the processor 53B transmits, to the computer 101A which is a request source, a compressed data group which is a collection of compressed data for each piece of block data of the first size (each first block unit) and a guarantee code group which is a collection of corresponding guarantee codes, and ends the processing.

Next, a processing operation of estimation model processing in the computer 101B will be described.

FIG. 12 is a diagram showing the estimation model processing according to the first embodiment.

The present processing is an example processing of the estimation model 704a and the estimation model 714a (executed by the compression processing unit 702 and the decompression processing unit 712) (simply referred to as an estimation model). The estimation model processing is an example of a case of implementing processing of the estimation model using a neural network, and is executed by inputting data (estimation data) used to estimate a data unit for which an appearance probability is to be estimated (estimation target data unit), thereby outputting a feature map (data input to the mixer model) of a location corresponding to the estimation target data unit. For example, the present processing can be executed in parallel as a thread for each dimension of the number of batches (B) operated in the core 62B of the parallel processing device 61B.

Wherein, the input data is an array of the number of batches (B)×the number of channels (C)×length of partial data (N). Note that during estimation model learning and compression, since all pieces of compression target data are stored, a plurality of pieces of estimation target data (N direction) can be processed collectively in parallel after matching a causal relationship of the data. FIG. 12 shows a case where data is processed collectively. On the other hand, during decompression (decoding), since data for which decoding is not completed is not stored, an operation in this case will be described with reference to FIG. 13.

The estimation model processing is mainly implemented by functional components such as input data shift processing (S121), a down scale block (DB) (S122), a residual block (RB) (S123), and an up scale block (UB) (S124) (hereinafter, the components will be collectively referred to as scale causal blocks (SCB)).

The input data shift processing (S121) is processing of padding the input data by one piece at the head in a length (N) direction and deleting one piece from the end. By this processing, the input data is moved by one piece to the past in the length (N) direction, and accordingly, subsequent processing is processing of estimating a next piece of input data from the past data.

The down scale block (S122) is processing of processing the input data with a convolutional neural network, dividing the data in a channel dimension direction (C direction), and then reducing the length (N) direction. Specifically, first, data being processed is padded with a predetermined size (for example, K−1 pieces) (indicated by black “0” in FIG. 12) at the head in the length (N) direction, and a convolutional neural network (Convolution in the drawing) is processed. In the example, since the length (N) direction is one-dimensional, a one-dimensional convolutional neural network is applied. Note that a Kernel size of the convolutional neural network is K, and a stride width is 1. For example, the Kernel size may be set to K=2 from the viewpoint of a range of receptive fields relative to the number of weights in the neural network. Thereafter, an activation function (Activation in the drawing) is applied to the data being processed (output result of the convolutional neural network). A function such as a scaled exponential linear unit (SELU) or a rectified linear unit (ReLU) may be used as the activation function. Thereafter, the data being processed is divided (Split in the drawing) in the channel dimension direction (C direction). A part of division data is used as a direct input to the subsequent corresponding up scale block (S124) without executing processing of the subsequent down scale block (S122). Accordingly, it is possible to prevent the loss of fine-grained information due to the processing of reducing the length (N) direction by the down scale block (S122), and to further improve accuracy of the estimation model processing. Processing of a memory model (Mem. in the drawing) may be applied to a part of the division data. The memory model is processing for improving probability estimation accuracy by storing history information in the length direction. The memory model may be implemented in a form of a residual block, as shown in a diagram of the down scale block (S122). Thereafter, processing (Down in the drawing) of reducing the data being processed in the length (N) direction is executed. The reduction processing may be executed, for example, by replacing two consecutive pieces of data in the length (N) direction in the channel (C) direction, as shown in FIG. 12. In another method, processing may be executed using a convolutional neural network with a wide stride width, or a method such as pooling may be used. In S122 of FIG. 12, an overview of the above processing is shown, and a number in the drawing represents a number corresponding to an order in the length (N) direction of an input data unit, and in processing after Convolution, a number in the drawing represents a causal relationship between the number of the order of input data and a processing result corresponding to the number (maximum value of the number corresponding to information used in the processing). In the above processing, the causal relationship in the length (N) direction of the input data is saved. In other words, since information after a certain target data unit is not used in processing, the processing is established as estimation processing.

The residual block (S123) is processing in which the data output from a preceding functional component is processed by a dilated convolutional neural network, and the processed data and unprocessed data are added. Specifically, first, data being processed is padded with a predetermined size (for example, d*(K−1) pieces) at the head in the length (N) direction, and then is processed by the dilated convolutional neural network. In the example, since the length (N) direction is one-dimensional, a one-dimensional convolutional neural network is applied. Note that the Kernel size of the dilated convolutional neural network is K (for example, K=2), the stride width is 1, and a dilated size d is Kx−1, wherein, x is a level of the residual block, and when r residual blocks are configured as shown in FIG. 12, the order of processing is designated by a natural number from 1 to r. By increasing a dilated size for each the hierarchy level as described above, receptive fields in the length (N) direction can be efficiently widened. Thereafter, an activation function is applied in a similar manner to the down scale block (S122). Thereafter, the processed data and the unprocessed data are added to be an output result of the residual block (S123). In addition to the addition processing, attention processing (such as self-attention) may be introduced. In the above processing, as shown in S123 of FIG. 12, it can be understood that the causal relationship in the length (N) direction of the input data is saved in a similar manner to the down scale block (S122), and the processing is established as estimation processing.

The up scale block (S124) expands data output from a preceding functional component in the length (N) direction, combines data divided by the preceding corresponding down scale block (S122) and outputs the data processed by a convolutional neural network. Specifically, first, the data being processed is padded with a predetermined size (for example, K−1 pieces) at the head in the length (N) direction, and then expanded in the length (N) direction (Up in the drawing). For example, as shown in FIG. 12, in reverse processing of Down of the down scale block (S122), the processing may be executed by dividing data into two pieces in the channel (C) direction, and replacing two consecutive pieces of data in the length (N) direction. In another method, processing may be executed using a transposed convolutional neural network with a widened stride width. For data being processed that has the same length in the length (N) direction and is divided in the corresponding down scale block (DBx), the data is padded with a predetermined size (for example, K−1 pieces) at the head in the length (N) direction to create data combined in the channel (C) direction with the data being processed that is expanded in the length (N) direction. The data is processed by a convolutional neural network. In the example, since the length (N) direction is one-dimensional, a one-dimensional convolutional neural network is applied. Note that the Kernel size of the convolutional neural network is K (for example, K=2), and the stride width is 1. Thereafter, the activation function is applied to the data being processed (an output result of the convolutional neural network) in a similar manner to the down scale block (S122), and data of a result is obtained. In the above processing, as shown in S124 of FIG. 12, it can be understood that a causal relationship in the length (N) direction of the input data is saved in a similar manner to the down scale block (S122), and the processing is established as estimation processing.

As a method of configuring the functional components described above, for example, as shown in FIG. 12, first, a plurality(s) of the down scale blocks (S122) (DB1 to DBs) may be processed, then a plurality (r) of the residual blocks (S123) (RB1 to RBr) may be processed, and then a plurality(s) of the up scale blocks (S124) (UB1 to UBs) may be processed. By processing in such a manner, the number of elements in the input data of B×C×N can be reduced to B×C1×N/2, B×C2×N/4 in the length (N) direction, the number of internal channels C1 to Cs can be efficiently increased, and thus processing of the estimation model can be made more efficient and faster. Note that C1 to Cs may be increased along with a reduction in the length (N) direction when processing the down scale block (S122), and may be decreased along with an increase in the length (N) direction when processing the up scale block (S124). It is possible to have a wide receptive field with a length of Ks+r by combining the down scale block (S122), the residual block (S123), and the up scale block (S124). In other words, it is possible to efficiently increase a data volume (estimation data) used to estimate a data unit for which an appearance probability is to be estimated (estimation target data unit), and thus estimation accuracy for a predetermined processing amount can be improved. The residual block (S123) may be processed between a plurality of the down scale blocks (S124) or between a plurality of the up scale blocks (S124).

In a configuration using s down scale blocks (S122) and s up scale blocks (S124), the number of parameters of an estimation model may be reduced by sharing weights of convolution layers of w blocks (RBs-w to RBs and UBs-w to UBs) (parameters of the RBs-w to RBs convolution layers are the same as parameters of the RBs-w convolution layer, and parameters of the UBs-w to UBs convolution layers are the same as parameters of the UBs-w convolution layer). Reducing the number of parameters of the estimation model can reduce a data volume of the model information 120d in the block data storage information 120, and thus compression efficiency can be improved by appropriately setting w.

Receptive fields may be further expanded by increasing the Kernel size (K) according to a layer depth(s) of the down scale block (S122) or the up scale block (S124).

The length (N) direction may be made multidimensional for multidimensional data such as image data. In this case, similar processing may be executed using a convolutional neural network of a corresponding dimension.

Next, a data flow of the estimation model processing and the mixer model processing in the computer 101B will be described.

FIG. 13 is a diagram showing a data flow of the estimation model processing and the mixer model processing according to the first embodiment.

A mixer processing model 1300 is an example of a method for implementing the estimation model 704a and the estimation model 714a (executed by the compression processing unit 702 and the decompression processing unit 712) (simply referred to as an estimation model), and the mixer model 704b and the mixer model 714b (executed by the compression processing unit 702 and the decompression processing unit 712) (simply referred to as a mixer model). The estimation model processing and the mixer model processing are the estimation model processing and the mixer model processing described in FIG. 12, and how data is processed within the processing will be described, including an overall overview. Initially input data is an array of the number of batches (B)×the number of channels (C)×length of partial data (N) in a similar manner to that shown in FIG. 12, while in FIG. 13, a dimension of the number of batches (B) is omitted, a horizontal axis represents a length (N) of partial data, a vertical axis represents an order of each processing, and the vertical axis in each processing represents the number of channels (C). For example, the present processing can be executed in parallel as a thread for each dimension of the number of batches (B) operated in the core 62B of the parallel processing device 61B.

The present example shows processing of estimating an eighth piece of data from the head in training data. Here, an eighth data unit is a data unit for which an appearance probability is to be estimated (estimation target data unit), and data used for estimation (estimation data) corresponds to a calculation part 1301 and a reference part 1302 in the drawing. The reference part 1302 also includes a result (for example, stored as a cache) calculated in the past (in a data unit that was already estimated).

In the present example, the estimation model processing is implemented by two down scale blocks (S122) (DB1, DB2), one residual block (S123) (RB1), and two up scale blocks (S124) (UB1, UB2), and the mixer model processing is implemented by a linear neural network (similar to convolution with K=1) and a Softmax function. In the estimation model processing, a feature map of a location corresponding to an estimation target data unit (data input to the mixer model) is output, and in the mixer model processing, an estimation result of an appearance probability of the estimation target data unit is finally output.

A number in the drawing represents a number corresponding to an order in the length (N) direction of an input data unit, and in each processing, the number in the drawing represents a causal relationship between the number of the order of input data and a processing result corresponding to the number (maximum value of the number corresponding to information used in the processing). As a result of the mixer model processing, the causal relationship in the length (N) direction of the input data is saved. In other words, since information after a certain target data unit is not used in processing, the processing is established as estimation processing.

For the estimation model processing, processing is proceeded in the same manner as the method described in FIG. 12. However, in the present example, to proceed calculation of the calculation part 1301 in the drawing, data of the reference part 1302 is cached in a state where overlapping is removed during calculating past (seventh or earlier) appearance probabilities, and by using the cached data, the calculation of the calculation part 1301 can be proceeded efficiently. In such a manner, even when it is difficult to execute calculation collectively in the length (N) direction during decoding, high-speed processing can be achieved through efficient iteration processing that prevents overlapping of calculations.

For the mixer model processing, a case where one estimation model is used in the present example. Alternatively, a plurality of estimation models may be used in a similar manner. In this case, an input dimension of the neural network of the mixer model increases. In the present example, an appearance probability in the case of 1 bit (=21) is calculated using the Softmax function. Alternatively, for example, one output in the channel direction may be converted into a value between 0 and 1 using a Sigmoid function, and may be treated as a probability of outputting a symbol “1”. In this case, a value obtained by subtracting the probability from 1 is a probability of outputting a symbol “0”.

In a method for learning a weight of a neural network in the estimation model processing and the mixer model processing, in the above description, the estimation model processing and the mixer model processing are implemented by differentiable processing. Therefore, estimation accuracy may be improved by calculating a relative entropy (or negative log likelihood, and the like) using an appearance probability of each symbol finally output by the mixer model and the training data (for example, a value corresponding to an appearance probability of each symbol expressed in a one-hot format), and by learning the model end-to-end using an error backpropagation method or the like to minimize the value. As for a timing of the learning, the learning may be carried out along the progress of the estimation processing in data units as shown in FIGS. 8 and 9, or a model in a pre-trained state may be used. As in the overall learning processing (S12), the estimation model and the mixer model may be learned periodically based on data stored in the memory 52B, the memory 63B, the persistent storage device 54B, and the like of the computer 101B. In this case, the learned model is saved in the persistent storage device 54B and the like, and a correspondence relationship between the model and data compressed by the model is recorded together with the compressed data 120a of the block data storage information 120 (model information 120d) to make restoration possible. A dedicated learned model may be prepared for similar data to improve compression efficiency by differentiating a model to be used based on identification information (code) representing features of the data.

Next, an algorithm of the estimation model processing in the computer 101B will be described.

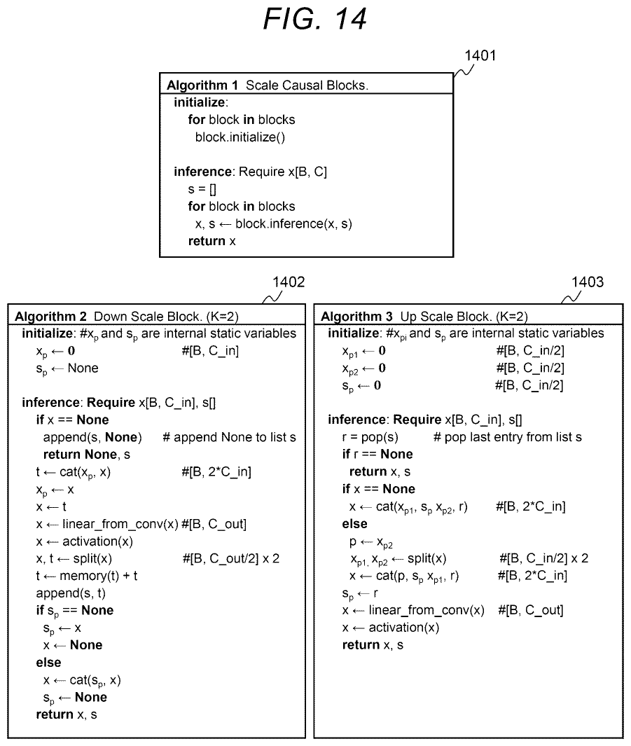

FIG. 14 is a diagram showing the algorithm of the estimation model processing according to the first embodiment.

In FIG. 12, components of the SCB (down scale block, up scale block, and the like) that configure the estimation model are described. In the description of the module in FIG. 12, a convolution Kernel is used as a neural network, and learning processing is generally executed in parallel (dividing and processing data for each Kernel size) in the length (N) direction. In this case, since a large number of data are input to the neural network in the length (N) direction, multiplicity in a batch (B) direction is set to be relatively small (for example, 16). This is a suitable processing method in the overall learning processing (S12) in the compression processing. However, when operating as inference processing such as estimation model processing (S13 and S23), the batch multiplicity is set to be higher (for example, several thousand or more) because the processing is iteration processing in symbol units. Therefore, as described in FIG. 13, by using a cache of intermediate data output from each component and by partially proceeding the calculation processing in the length (N) direction, it is possible to improve memory usage efficiency and increase the degree of multiplicity in the batch (B) direction to various levels (for example, several thousand or more). Hereinafter, the inference processing will be specifically shown and described as an algorithmic procedure in FIG. 14.

First, an overall algorithm 1401 of SCB mainly includes initialization processing (initialize in the drawing) and inference processing (inference in the drawing). The initialization processing is processing executed only at initial execution when executing the estimation model processing (S13 and S23) on processing target data (B×C×N array) obtained by dividing compression target data into a plurality of pieces of partial data. The inference processing is processing that takes one piece of the processing target data in the length (N) direction (x expression, B×C array in the drawing) as an input, and is executed every iteration (executed N times) as the estimation model processing (S13 and S23). Note that the notation [X, Y] in the drawing represents a shape of an X×Y array (tensor), and [ ] represents an empty list structure. In the initialization processing, the initialization processing is executed for each component (block in the drawing) in the overall component configuration of the SCB (expressed as blocks in the drawing, and in which each component such as DB1, DB2, UB2, and UB1 is listed in the order of processing). In the inference processing, as shown in the algorithm 1401 in the drawing, the inference processing is executed for each component in order.

Next, an algorithm 1402 of the down scale block will be described. In the drawing, an algorithm in the case of Kernel size K=2 is described as an example. Processing of the down scale block mainly includes initialization processing (initialize in the drawing) and inference processing (inference in the drawing). In the initialization processing, initial values are respectively set for variables (xp and sp) used as two types of caches. Note that “0” in boldface in the drawing represents an array initialized with zero. The inference processing takes, as an input, an array (x) of processing target data of B×C_in and a list(s) of arrays of data to be input to each subsequent up scale block, and outputs an array of B×C_out (values of C_in and C_out may be different for each component). A basic operation of the inference processing is as shown in the algorithm described in FIG. 14, and since an overview of the operation is already described in FIG. 13, details will be omitted, and only a feature part of the inference processing will be described below. linear_from_conv in the drawing is processing in which the convolution processing described in FIG. 12 is replaced with a fully connected layer. Specifically, the convolution processing can be regarded as a fully connected layer with K×C_in as an input and C_out as an output, and accordingly the processing is executed after converting a convolution kernel parameter into a parameter of the fully connected layer. Accordingly, processing such as intermediate array dimension conversion can be omitted and processing can be executed at high speed. As shown in the algorithm 1402, memory model processing (memory in the drawing) may be executed.

Next, an algorithm 1403 of the up scale block will be described. In the drawing, an algorithm in the case of Kernel size K=2 is described as an example. Processing of the up scale block mainly includes initialization processing (initialize in the drawing) and inference processing (inference in the drawing). In the initialization processing, initial values are respectively set for variables (Xp1, Xp2, and Sp) used as two types of caches. The inference processing takes, as an input, an array (x) of processing target data of B×C_in and a list(s) of arrays of data input to each up scale block, and outputs an array of B×C_out.

As described above, by using a cache of intermediate data output by each component, and by proceeding partial calculation processing in the length (N) direction (processing in units of B×C array), it is possible to improve memory usage efficiency, increase the degree of multiplicity in the batch (B) direction to various levels (for example, several thousand or more), and the processing can be executed at high speed.

Next, a configuration of cache information table used in the estimation model processing in the computer 101B will be described.

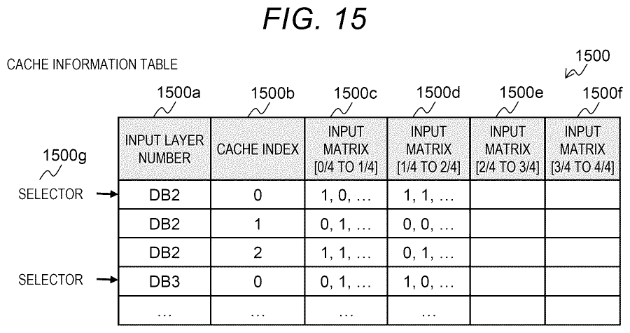

FIG. 15 is a configuration diagram showing the cache information table according to the first embodiment.

As shown in FIG. 14, the algorithm 1402 of the down scale block has internal variables x_p and s_p. As shown in FIG. 14, the algorithm 1403 of the up scale block has internal variables of x_p1, x_p2, and s_p. The internal variables are used in the estimation model processing in an iteration loop including steps S13 to S20 in which the coding processing is executed on all data units of the partial data shown in FIG. 8 and steps S23 to S30 in which the decoding processing is executed on all data units of the partial data shown in FIG. 9, wherein, in order to efficiently execute the estimation model processing, such information (collectively referred to as cache information) is managed in the cache information table. FIG. 15 shows the cache information table in a case where the Kernel size K=2. Hereinafter, processing corresponding to linear_from_conv in the algorithm 1402 of the down scale block and the algorithm 1403 of the up scale block shown in FIG. 14 is referred to as matrix multiplication processing, processing corresponding to activation is referred to as activation function processing, and weight data used in linear_from_conv is referred to as a weight matrix, wherein, a configuration of a neural network that executes the matrix multiplication processing corresponds to conversion processing (first conversion processing (for example, linear_from_conv in FIG. 14)), and a configuration of a neural network that executes the activation function processing corresponds to conversion processing (second conversion processing (for example, activation in FIG. 14)).

Here, a size of a matrix of N rows×M columns is denoted by [N, M]. A cache information table 1500 is a table for managing cache information, and includes entries for each input matrix (matrix size: [B, C_in]) input to each layer. That is, one entry (row) of the cache information table 1500 stores input information necessary for outputting one calculation part 1301 calculated in a layer in FIG. 13. Entries of the cache information table 1500 include fields of an input layer number 1500a, a cache index 1500b, and input matrices 1500c, 1500d, 1500e, and 1500f (matrix size of each input matrix: [B, C_in/4]). The input layer number 1500a stores a number of a layer to which an input matrix corresponding to an entry is input. The cache index 1500b stores an ID of a column corresponding to an entry. Each of the input matrices 1500c, 1500d, 1500e, and 1500f stores a part of an input matrix divided into four sections in an C_in direction.

The cache information table 1500 includes a selector 1500g for specifying a row to be input next time for each layer. In the estimation model processing, each time processing of a layer corresponding to the specified entry is executed, the selector 1500g selects a row corresponding to the same layer such that a value of the cache index 1500b in the specified row circulates in a manner of 0→1→2→0→ . . . .

Next, processing of writing an input matrix into an entry of the cache information table 1500 will be described, wherein, processing of writing, into the cache information table 1500, the calculation part 1301 corresponding to the seventh symbol in the length direction in the layer DB1 in the estimation model processing and the mixer processing model 1300 in FIG. 13 will be described as an example.

The calculation part 1301 of DB1 corresponding to the seventh symbol in the length direction is used as the reference part 1302 (input) of subsequent four calculation parts 1301. That is, there are an input x of the calculation part 1301 of DB2 corresponding to the seventh symbol in the length direction, an input x_p of the calculation part 1301 of DB2 corresponding to the ninth symbol in the length direction, an input r of the calculation part 1301 of UB1 corresponding to the seventh symbol in the length direction, and an input s_p of the calculation part 1301 of UB1 corresponding to the ninth symbol in the length direction.

First, an input to DB2 after the calculation part 1301 of DB1 corresponding to the seventh symbol in the length direction is split will be described. As described above, the calculation part 1301 includes the input x of the calculation part 1301 of DB2 corresponding to the seventh symbol in the length direction and the input x_p of the calculation part 1301 of DB2 corresponding to the ninth symbol in the length direction. In the estimation processing model and the mixer processing model 1300, when the seventh symbol in the length direction is processed, data of the calculation part 1301 of DB1 corresponding to the seventh symbol is last partial data when an input matrix of DB2 is divided into four sections in the C_in direction. Accordingly, the data is overwritten in the fourth input matrix 1500f of the cache information table 1500 where the last partial data is stored in a row selected by the selector of DB2 when the data is the seventh symbol in the length direction, that is, a row currently selected by the selector of DB2 in the present example. In the estimation processing model and the mixer processing model 1300, when a ninth symbol in the length direction is processed, data of the calculation part 1301 of DB1 corresponding to the seventh symbol is second partial data from the head when the input matrix of DB2 is divided into four sections in the C_in direction. Accordingly, the data is also overwritten in the second input matrix 1500d in the cache information table 1500 in a row selected by the selector of DB2 when the data is the ninth symbol in the length direction, that is, a row selected subsequently by the selector of DB2 in the present example.

Next, an input to the UB1 after the calculation part 1301 of the DB1 corresponding to the seventh symbol in the length direction is split will be described. The calculation part 1301 is s_p or r in the algorithm 1403 of the down scale block shown in FIG. 14. Data of the calculation part 1301 is overwritten in the input matrix 1500f in a row selected by the selector of UB1 when the data is the seventh symbol in the length direction and overwritten in the input matrix 1500d in a row selected by the selector of UB1 when the data is the ninth symbol in the length direction in the estimation processing model and the mixer processing model 1300.

When an input matrix is read from the cache information table 1500 in the matrix multiplication processing, values of the input matrices 1500c, 1500d, 1500e, and 1500f of a row designated by the selector 1500g are simply combined and read as an input matrix.

In the cache information table 1500, storage areas of the input matrices 1500c, 1500d, 1500e, and 1500f in the same row may be arranged at consecutive addresses of the memory 63B, and storage areas of the input matrices 1500c, 1500d, 1500e, and 1500f in a row designated by the selector 1500g may be sequentially read by designating a head area during reading. For example, in an area of the memory 63B where the input matrices 1500c, 1500d, 1500e, and 1500f in the same row are stored, the input matrices 1500c, 1500d, 1500e, and 1500f may be stored in a 5th-order tensor type in which the number of elements in first and second dimensions is set to a size to be divided and processed by a calculation processor 1612 (for example, (B/128)×4×(C_in/4/128)×128×128). In this manner, reduction in a memory access time or the like can be expected, and thus estimation model processing can be efficiently executed. Although the cache information table 1500 is preferably stored in the memory 63B in order to constantly process the estimation processing model in the parallel processing device 61B, the cache information table 1500 may be stored in the memory 52B.

Next, a configuration of the parallel processing device 61 in the computer 101B will be described.

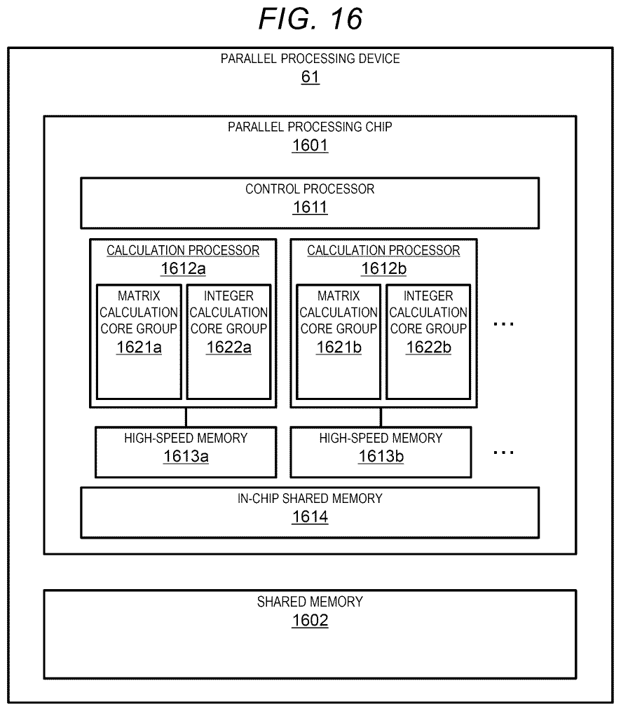

FIG. 16 is a configuration diagram showing the parallel processing device according to the first embodiment.

The parallel processing device 61 includes a parallel processing chip 1601 and a shared memory 1602. The parallel processing chip 1601 is, for example, a GPU chip. The shared memory 1602 is an example of a second memory, and is, for example, a dynamic random access memory (DRAM).

The parallel processing chip 1601 includes a control processor 1611, one or more calculation processors 1612 (1612a, 1612b . . . ), one or more high-speed memories 1613 (1613a, 1613b . . . ), and an in-chip shared memory 1614. The parallel processing chip 1601 processes data loaded from the shared memory 1602 in parallel and stores the data in the shared memory 1602.

The control processor 1611 is, for example, a massive thread management engine having a physical configuration. The control processor 1611 manages processing executed by the parallel processing chip 1601. The control processor 1611 implements parallel processing by dividing processing into sets of each of the calculation processors 1612 and the high-speed memory 1613. The calculation processor 1612 is, for example, a calculator cluster having a physical configuration. The calculation processor 1612 processes data loaded from the high-speed memory 1613 using a matrix calculation core group 1621 and an integer calculation core group 1622 to be described later, and stores a calculation result in the high-speed memory 1613.

The high-speed memory 1613 is an example of a first memory, and is, for example, a register. The high-speed memory 1613 is connected to one calculation processor 1612, and can be accessed exclusively by the calculation processor 1612. The high-speed memory 1613 stores data necessary for processing executed by the calculation processor 1612, a calculation result of the calculation processor 1612, and the like. The in-chip shared memory 1614 is, for example, a level 2 (L2) cache. The in-chip shared memory 1614 can be accessed by each calculation processor 1612. The in-chip shared memory 1614 may be used as an intermediary to efficiently transfer data from the shared memory 1602 to each high-speed memory 1613.

The calculation processor 1612 includes the matrix calculation core group 1621 including a plurality of matrix calculation cores and the integer calculation core group 1622 including a plurality of alignment calculation cores. The matrix calculation core group 1621 is, for example, a calculation unit specialized for a matrix multiplication having a physical configuration. The integer calculation core group 1622 is, for example, a general-purpose integer calculation unit having a physical configuration.

The shared memory 1602 stores data and a calculation result necessary for parallel processing.

Wherein, the matrix calculation cores of the matrix calculation core group 1621 and/or the integer calculation cores of the integer calculation core group 1622 and/or the control processor 1611 correspond to the core 62B, and a general term of the shared memory 1602, the in-chip shared memory 1614, and the high-speed memory 1613 corresponds to the memory 63B.

A speed and a capacity when reading and writing data from and to the high-speed memory 1613, the in-chip shared memory 1614, and the shared memory 1602 may be different from one another. For example, the memories may be arranged in order of speed from fastest to slowest as the high-speed memory 1613, the in-chip shared memory 1614, and the shared memory 1602. For example, the memories may be arranged in order of capacity from largest to smallest as the shared memory 1602, the in-chip shared memory 1614, and the high-speed memory 1613.

Next, the matrix multiplication processing and the activation function processing executed in the estimation model processing will be described.

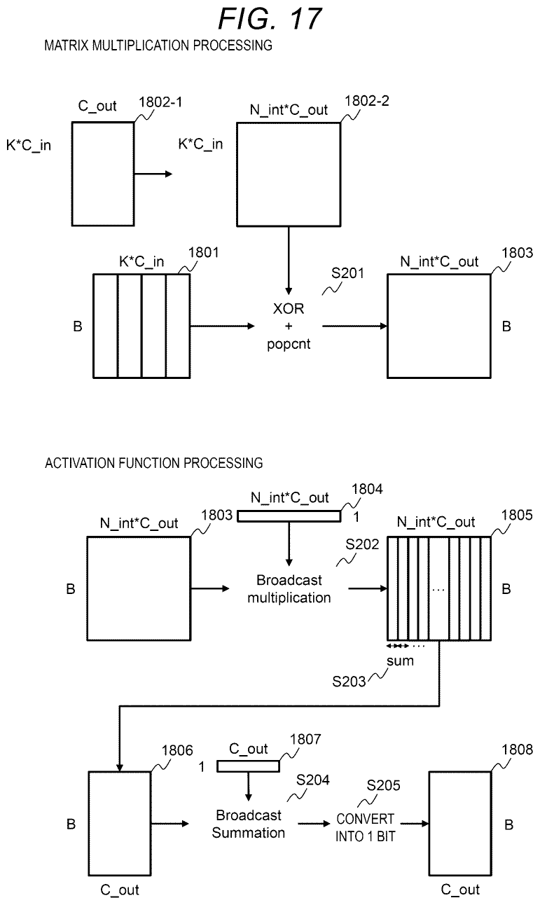

FIG. 17 is a diagram showing the matrix multiplication processing and the activation function processing according to the first embodiment. In FIG. 17, processing in the entire parallel processing device 61 will be described.

First, the matrix multiplication processing will be described. An input matrix 1801 input to a layer for executing the matrix multiplication processing is [B, K×C_in], and each element is a 1-bit integer of 0 or 1. The input matrix 1801 is loaded from the input matrices 1500c, 1500d, 1500e, and 1500f of an entry in the cache information table 1500 corresponding to the layer. In the matrix multiplication processing, a quantized weight matrix 1802-1 (calculation matrix) for performing calculation on the input matrix 1801 is [K×C_in, C_out], wherein, an integer N_int is integer accuracy of the layer, and each element of the quantized weight matrix 1802-1 is an N_int bit. In the present embodiment, the matrix calculation core of the matrix calculation core group 1621 that executes matrix calculation processing is configured to execute calculation on matrices each having an element of 1 bit, and thus, in the case of a matrix in which each order of bits of each element of the quantized weight matrix 1802-1 is a 1-bit element, the quantized weight matrix 1802-1 is a quantized weight matrix 1802-2 (virtual matrix) of [K×C_in, N_int×C_out] in which each element is 1 bit.

In the matrix multiplication processing, an XOR (exclusive or) calculation for each element is executed on all combinations of rows of the input matrix 1801 and columns of the quantized weight matrix 1802-2 using the matrix calculation core group 162, and then a popcnt calculation (calculation of counting the number of elements of 1) is executed (S201), and a matrix multiplication result 1803 (calculation result) is obtained and stored in the high-speed memory 1613. The matrix multiplication result 1803 is [B, N_int×C_out], and each element is, for example, 32 bits.

Next, the activation function processing will be described. In the activation function processing, the matrix multiplication result 1803, coefficient data 1804, and bias data 1807 are used. The coefficient data 1804 is data generated when the weight matrix quantization processing (refer to FIG. 18) is executed, and is data indicating how many times a quantum bit is multiplied to obtain a quantized value, in other words, data reflecting an order in an element of the quantized weight matrix 1802-1 on data of each column of the matrix multiplication result 1803, and is a matrix of [1, N_int×C_out]. For example, the quantized weight matrix 1802-1 is determined in step S216 to be described later. The bias data 1807 is data for biasing, and is a matrix of [1, C_out].

In the activation function processing, Broadcast_multiplication processing (S202) is executed on the matrix multiplication result 1803 and the coefficient data 1804 to obtain coefficient processed data 1805. In the Broadcast_multiplication processing (S202), each row of the coefficient processed data 1805 is obtained by multiplying each row of the matrix multiplication result 1803 by each element in a column direction of the coefficient data 1804, wherein, the coefficient processed data 1805 is [B, N_int×C_out], and each element is, for example, 32 bits. The coefficient processed data 1805 is a matrix resulting from the matrix multiplication result 1803.

Next, adjacent summation processing (S203) of summation each N_int column in the column direction is executed on the coefficient processed data 1805 to obtain summation processed data 1806 (summed matrix). In the adjacent summation processing, for example, when N_int=2, a first column and a second column of the coefficient processed data 1805 are added to each element in a row direction to obtain a first column of the summation processed data 1806, and similarly, a second column of the summation processed data 1806 is obtained from a third column and a fourth column of the coefficient processed data 1805, and the same processing is executed on the other columns. The summation processed data 1806 is a matrix of [B, C_out], and each element is, for example, 32 bits. The summation processed data 1806 corresponds to a result of executing the XOR calculation and the popcnt operation on the input matrix 1801 and the quantized weight matrix 1802-1. Accordingly, it is possible to obtain a processing result of the XOR calculation and the popcnt calculation of the configuration input matrix 1801 and the quantized weight matrix 1802-1 by using a matrix calculation core 1621a or the like that executes calculation on matrices each having an element of 1 bit.

Next, Broadcast_summation processing (S204) is executed on the summation processed data 1806 and the bias data 1807. In the Broadcast_summation processing (S204), elements of each row of the bias data 1807 are added to elements of each row of the summation processed data 1806 to obtain each row. Thereafter, 1-bit conversion processing (S205) is executed in which each element of a result of the Broadcast_summation processing (S204) is convert to an integer of 1 bit to obtain a calculation result 1808 (processing result), and the calculation result 1808 is stored in the high-speed memory 1613. The calculation result 1808 is a matrix of [B, C_out], and each element is an integer of 1 bit. In the 1-bit conversion processing (S205), for example, when a processing result of the Broadcast_summation processing (S204) is larger than K×C_in/2, the calculation result may be set as 0, and otherwise, may be set as 1.

According to the matrix multiplication processing and the activation function processing, since the calculation result 1808 is a matrix of [B, C_out] and each element is an integer of 1 bit, it is possible to reduce the entire data volume and store the data in the high-speed memory 1613, and it is possible to reduce a writing time when writing data from the high-speed memory 1613 to the shared memory 1602 or the like for subsequent processing.

Next, the weight matrix quantization processing (S12-3, S22-2) will be described.

FIG. 18 is a flowchart showing the weight matrix quantization processing according to the first embodiment. Although each processing of the weight matrix quantization processing is assumed to be executed by the processor 53B in the following description, at least a part of each processing may be executed by the parallel processing device 61B.

First, the processor 53B executes processing of creating a look up table (LUT) (S213). The LUT is a table for managing a calculation result in a managed layer for all input candidates that can be inputs to the layer. The LUT is created in relation to all input candidates that can be inputs to the layer to be managed, and is created by executing the matrix multiplication processing and the activation function processing on the layer and calculating a calculation result. The LUT may manage only input candidates and calculation results for a part of processing in the layer, for example, the matrix multiplication processing.

A weight matrix used in the matrix multiplication processing when creating the LUT may be executed using a weight matrix having elements with higher bits than the weight matrix in the matrix multiplication processing shown in FIG. 17. For example, a weight matrix obtained by converting each element into 8 bits may be used. Since there are 2K types of input values that can be inputs per batch, for example, the LUT related to DB1 can be created by executing the processing of DB1 for all of the input values and storing calculation results as a table. In this case, the input values may be processed in parallel by being arranged in a batch direction.

Whether to create the LUT may be determined for each layer. Since the usage of the memory 63B and a processing time required to create the LUT increase as the LUT is created in more layers, a layer in which the LUT is created may be determined by comprehensively considering the usage of the memory 63B and the processing time. For example, the LUT may be created for DB1, DB2, DB3, and DB4, and the LUT may be created for UB1, UB2, UB3, and UB4 only for a part of the matrix multiplication processing. By creating the LUT, it is possible to reduce the number of times of processing of the matrix multiplication processing and the activation function processing in the estimation model processing, and it is possible to execute the estimation model processing at high speed. In addition, by creating the LUT using a weight matrix having a high number of bits, it is possible to prevent a decrease in a compression rate due to a quantization error as compared with a case where the LUT is not used.

In step S214, the processor 53B determines whether the integer accuracy for each layer is undetermined. Regarding whether the integer accuracy for each layer is undetermined, for example, when the integer accuracy for each layer is not stored in the model information 120d of the block data storage information 120, it is determined that the integer accuracy for each layer is undetermined, and when the integer accuracy is stored, it is determined that the integer accuracy is determined.

As a result, when it is determined that the integer accuracy for each layer is undetermined (S214: Y), the processor 53B executes integer accuracy determination processing of determining the integer accuracy for each layer (S215). When a large value is adopted as the integer accuracy, deterioration of the compression rate due to a quantization error can be prevented, but a processing time is increased. Therefore, in the integer accuracy determination processing, both the compression rate and the processing time are comprehensively taken into consideration. In the integer accuracy determination processing, for example, the integer accuracy is determined by using a greedy method based on inference accuracy improvement efficiency of each layer or a method of using a fixed value of N_int=1 in all layers.

Hereinafter, an example of the integer accuracy determination processing for each layer will be described. The processor 53B creates random sample data by randomly extracting a specific number (for example, 1024) of pieces of partial data units from compression target data. Thereafter, the processor 53B compresses the random sample data using the compressor 70B (wherein, assumed to be a compressor 70Ba) in which N_int=1 in all layers and the compressor 70B (wherein, assumed to be a compressor 70Bb) in which N_int=2 in a specific layer, and obtains a compression rate. In this case, a plurality of types of the compressors 70Bb may be prepared. The compressor 70Ba and the compressor 70Bb may be configured to execute processing in parallel in the parallel processing device 61. The processor 53B derives the inference accuracy improvement efficiency based on a compression rate when a plurality of the compressors 70B are used, wherein, the inference accuracy improvement efficiency may be (compression rate when the compressor 70Ba is used)−(compression rate when the compressor 70Bb is used)/(processing time when the compressor 70Bb is used)−(processing time when the compressor 70Ba is used). Terms for calculating the inference accuracy improvement efficiency may use estimated values. Based on the derived inference accuracy improvement efficiency, both the compression rate and the processing time can be taken into consideration comprehensively by, for example, using a greedy method, and the processor 53B may determine accuracy for each layer so as to satisfy a required criterion of the compression rate or the processing time.

On the other hand, when it is determined that the integer accuracy for each layer is not undetermined (S214: N), since the integer accuracy was determined, the determined integer accuracy is used, and the processor 53B proceeds the processing to step S216.

In step S216, the processor 53B executes quantization processing of quantizing a weight matrix to obtain the determined integer accuracy and calculating the quantized weight matrix 1802-1 and the coefficient data 1804. For example, the processor 53B generates the quantized weight matrix 1802-1 by applying a sign function to each element of the weight matrix, and calculates the coefficient data 1804 so as to minimize a square error between the weight matrix and a product of the quantized weight matrix 1802-1 and the coefficient data 1804. For example, when each element of the quantized weight matrix 1802-1 is 2 bits, the coefficient data 1804 is 1, 2, 1, 2 . . . .

In step S217, the processor 53B adds model data including a result of the quantization processing to the model information 120d. Contents added to the model information 120d may include, for example, the quantized weight matrix 1802-1, the integer accuracy of each layer, and the coefficient data 1804.

Next, the matrix multiplication processing will be described.

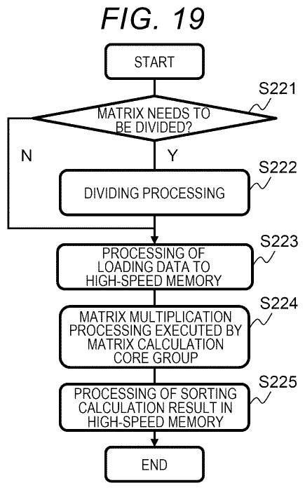

FIG. 19 is a flowchart showing the matrix multiplication processing according to the first embodiment. The matrix multiplication processing is started by the control processor 1611 in the estimation model.

First, the control processor 1611 determines whether the matrix multiplication result 1803 needs to be divided (S221). The control processor 1611 determines whether the matrix multiplication result 1803 needs to be divided by referring to a storable size of the high-speed memory 1613, the number of the matrix calculation core groups 1621, and the like. For example, when the matrix multiplication result 1803 has a size that cannot be stored in one high-speed memory 1613, the control processor 1611 determines that the matrix multiplication result 1803 needs to be divided.

As a result, when it is determined that the matrix multiplication result 1803 needs to be divided (S221: Y), the control processor 1611 divides a matrix to be input in the matrix multiplication processing (S222). A size of the matrix after the division is determined based on whether a size of a row and a column after the division in the matrix calculation core group 1621 is a size at which the estimation model processing is efficiently operated in a comprehensive manner from the viewpoint of a specification that the size of the row and the column after the division needs to be a predetermined value (for example, a multiple of 8), a size at which the matrix after the division can be stored in the high-speed memory 1613, and whether sequential read and write is possible when the shared memory 1602 is accessed. For example, the input matrix may be divided so that the matrix multiplication result 1803 is divided into a block matrix to share matrix multiplication of a size of 128×128.

On the other hand, when it is determined that the matrix multiplication result 1803 does not need to be divided (S221: N), subsequent processing is executed by one set of the calculation processor 1612 and the high-speed memory 1613, and the control processor 1611 proceeds the processing to step S223.

In step S223, the control processor 1611 executes processing of loading the input matrix 1801 and the quantized weight matrix 1802-2 (when the input matrix is divided in step S222, a part of the divided input matrix 1801 and a part of the necessary quantized weight matrix 1802-2) from the shared memory 1602 to the high-speed memory 1613. For example, when the matrix multiplication of the size of 128×128 is shared, the control processor 1611 loads 128 rows of the input matrix 1801 and 128 columns of the quantized weight matrix 1802-2 into a high-speed memory 1613a of the calculation processor 1612 that executes the processing. In this case, to achieve efficient data transfer, the input matrix 1801 and the quantized weight matrix 1802-2 may be transferred from the shared memory 1602 to the in-chip shared memory 1614, and a necessary part may be loaded from the in-chip shared memory 1614 to each high-speed memory 1613.

In step S224, the control processor 1611 loads the input matrix 1801 (or a part thereof) and the quantized weight matrix 1802-2 (or a part thereof) from the high-speed memory 1613, and causes the matrix calculation core group 1621 to execute the matrix multiplication.

Next, the matrix calculation core group 1621 executes processing of storing the matrix multiplication result 1803 in the high-speed memory 1613.

Next, the activation function processing will be described.

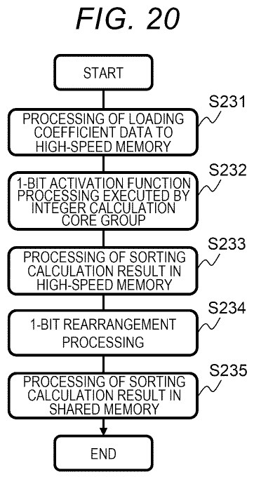

FIG. 20 is a flowchart showing the activation function processing according to the first embodiment. The activation function processing is started by the control processor 1611 after executing the matrix multiplication processing in the estimation model.

The control processor 1611 executes processing of loading the coefficient data 1804 into the high-speed memory 1613 (S231).

Next, the control processor 1611 causes the integer calculation core group 1622 to load the matrix multiplication result 1803, the coefficient data 1804, and the bias data 1807 from the high-speed memory 1613 and execute processing in steps S202, S203, S204, and S205 in FIG. 17 (S232). In this case, for example, a sign function may be adopted as a nonlinear function used when an element of a plurality of bits is converted into 1 bit in the 1-bit conversion processing in step S205. The sign function may be, for example, a function that returns to 0 when a calculation result is larger than half KC_in, and otherwise returns to 1.

Next, the integer calculation core group 1622 executes processing of storing the calculation result 1808 in the high-speed memory 1613 (S233).

Next, the control processor 1611 executes rearrangement processing for rearranging the calculation result 1808 (S234). The rearrangement processing is executed for making processing efficient in calculation result storing processing (S235) of storing a calculation result in the next shared memory 1602. In general, since a data layout in the high-speed memory 1613 at the time of being input to the matrix calculation core group 1621 and a data layout in the high-speed memory 1613 at the time of being output by the integer calculation core group 1622 may be different from each other, the rearrangement processing is processing of rearranging data so that the data layout at the time of output corresponds to the data layout at the time of input. For example, in general, in the parallel processing device 61, since threads managed by consecutive numbers can be efficiently stored in the shared memory 1602 when accessed by consecutive addresses, data held by each thread of the calculation result 1808 is rearranged to have consecutive addresses. The rearrangement processing may be executed in the high-speed memory 1613 in order to efficiently execute the processing.

Next, the control processor 1611 executes processing of storing a calculation result 1809 obtained by the rearrangement processing in the shared memory 1602. The calculation result 1809 may be managed in the cache information table 1500.

Next, a data flow of the matrix multiplication processing and the activation function processing in the parallel processing device 61 will be described.

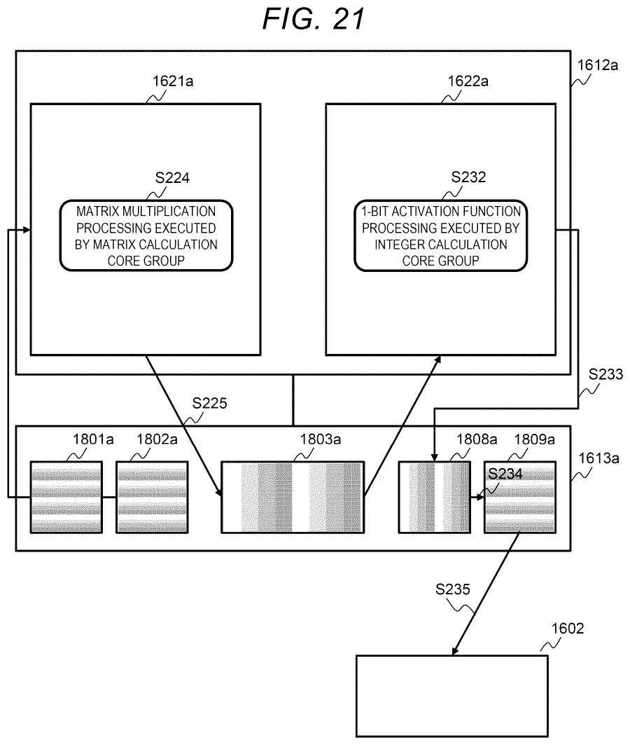

FIG. 21 is a diagram showing the data flow the matrix multiplication processing and the activation function processing in the parallel processing device according to the first embodiment. FIG. 21 shows a data flow of a set of the calculation processor 1612a and the high-speed memory 1613a when the control processor 1611 divides processing into a set of each calculation processor 1612 and each high-speed memory 1613 and executes the processing in parallel in the matrix multiplication processing and the activation function processing.

A division input matrix 1801a is a matrix obtained by dividing the input matrix 1801, and a partially quantized weight matrix 1802a is a matrix obtained by dividing the quantized weight matrix 1802. The matrix calculation core group 1621 reads the division input matrix 1801a and the division quantized weight matrix 1802a that are stored in the high-speed memory 1613a, and executes matrix multiplication processing (S224). Thereafter, the matrix calculation core group 1621 executes processing of storing a division matrix multiplication result 1803a in the high-speed memory 1613a (S225).

Thereafter, the integer calculation core group 1622a reads the division matrix multiplication result 1803a, and executes the activation function processing (S232). Thereafter, the integer calculation core group 1622a executes processing of storing a division calculation result 1808a in the high-speed memory 1613a (S233). Thereafter, if necessary, the control processor 1611 executes the rearrangement processing (S234) on data in the high-speed memory 1613a, and obtains a division rearranged calculation result 1809a which is a calculation result after the rearrangement. Next, the control processor 1611 executes processing of storing the division rearranged calculation result 1809a of the high-speed memory 1613a in the shared memory 1602 (S235).

In FIG. 21, each element of the division input matrix 1801a, the division quantized weight matrix 1802a, the division calculation result 1808a, and the division rearranged calculation result 1809a is an integer of 1 bit. On the other hand, each element of the division matrix multiplication result 1803a is an integer of a necessary number of bits such as 32 bits. In the present embodiment, an amount of access to the low-speed shared memory 1602 can be reduced and a processing time required for step S235 can be reduced by setting the division rearranged calculation result 1809a to 1 bit. In addition, by setting a result other than the division matrix multiplication result 1803a to an integer of 1 bit, it is possible to execute processing in the low capacity high-speed memory 1613a, and to efficiently execute the matrix multiplication processing and the activation function processing.

The invention is not limited to the above-described embodiment, and can be appropriately modified and implemented without departing from the gist of the invention.

For example, although the parallel processing device is different from the processor 53 (53A, 53B) in the above embodiment, when the processor 53 includes a plurality of cores, the processor 53 may be used as the parallel processing device.

In the above-described embodiment, a part or all of processing executed by a processor may be executed by a hardware circuit. Programs in the above-described embodiment may be installed from a program source. The program source may be a program distribution server or a recording medium (for example, a portable recording medium).

What is claimed is:

1. A data compression system for compressing data, the data compression system comprising:
a parallel processing device, wherein
the parallel processing device is configured to
divide compression target data into a plurality of pieces of partial data,
execute compression processing on the partial data in parallel,
calculate an appearance probability for each predetermined data unit of the partial data by using a neural network in the compression processing, and
output a coded bit string which is a bit string subjected to entropy coding for each data unit based on the data unit and the appearance probability, and
processing for implementing the neural network includes
first conversion processing of executing matrix multiplication processing, and
second conversion processing of inputting a processing result of the first conversion processing and converting each element of a matrix resulting from the processing result into an integer of 1 bit, subsequent to the first conversion processing.

2. The data compression system according to claim 1, wherein
the parallel processing device includes one or more calculation processors provided with a plurality of matrix calculation cores and a plurality of integer calculation cores, and
the parallel processing device is configured to
execute the first conversion processing using the matrix calculation cores, and
execute the second conversion processing using the integer calculation cores.

3. The data compression system according to claim 2, wherein
the calculation processor further includes a first memory connected to the matrix calculation cores and the integer calculation cores, and
the parallel processing device is configured to
store the processing result of the first conversion processing in the first memory, and
input the processing result of the first conversion processing stored in the first memory to the second conversion processing, and store a processing result of the second conversion processing in the first memory.

4. The data compression system according to claim 3, wherein
the parallel processing device rearranges a calculation result stored in the first memory into a layout in the first memory that matches a layout of input data input to the first conversion processing.

5. The data compression system according to claim 4, wherein
the parallel processing device stores, in a second memory having a larger capacity and a lower speed than the first memory, a calculation result obtained by rearranging the layout in the first memory.

6. The data compression system according to claim 3, wherein
the first memory stores an input matrix in which each element is 1 bit and a calculation matrix in which each element is a plurality of bits and matrix multiplication is executed with the input matrix,
the matrix calculation core executes calculation between matrices in which each element is 1 bit,
the matrix calculation core executes calculation between the input matrix and a virtual matrix in which, for each element having multiple bits in the calculation matrix, each order of the element is assumed to be an element of 1 bit, and stores a matrix of a calculation result in the first memory, and
the integer calculation core multiplies each element of the matrix of the calculation result by a coefficient corresponding to each element of the calculation matrix, generates a summed matrix in which a value obtained by summing values of a plurality of elements based on the same element of the calculation matrix serves as each element of a matrix obtained by the multiplication, and outputs a matrix obtained by converting each element of the summed matrix into 1 bit as the processing result of the second conversion processing.

7. A data compression program causing a computer to execute processing of compressing data, wherein
the computer includes a parallel processing device,
the parallel processing device is configured to
divide compression target data into a plurality of pieces of partial data,
execute compression processing on the partial data in parallel,
calculate an appearance probability for each predetermined data unit of the partial data by using a neural network in the compression processing, and
output a coded bit string which is a bit string subjected to entropy coding to the data unit based on the data unit and the appearance probability, and
processing of implementing the neural network includes
first conversion processing of executing matrix multiplication processing, and
second conversion processing of inputting a processing result of the first conversion processing and converting each element of a matrix resulting from the processing result into an integer of 1 bit, subsequent to the first conversion processing.

8. A data compression method executed by a data compression system for compressing data, wherein
the data compression system includes a parallel processing device,
the parallel processing device is configured to
divide compression target data into a plurality of pieces of partial data,
execute compression processing on the partial data in parallel,
calculate an appearance probability for each predetermined data unit of the partial data by using a neural network in the compression processing, and
output a coded bit string which is a bit string subjected to entropy coding to the data unit based on the data unit and the appearance probability, and
processing of implementing the neural network includes
first conversion processing of executing matrix multiplication processing, and
second conversion processing of inputting a processing result of the first conversion processing and converting each element of a matrix resulting from the processing result into an integer of 1 bit, subsequent to the first conversion processing.
